(19) United States
(12) Patent Application Publication
(10) Pub. No.: US 2019/0244666 A1
(43) Pub. Date: Aug. 8, 2019

(54) METHODS AND APPARATUS FOR MEMORY CELLS THAT COMBINE STATIC RAM AND NON VOLATILE MEMORY

(71) Applicant: Fu-Chang Hsu, San Jose, CA (US)

(72) Inventor: Fu-Chang Hsu, San Jose, CA (US)

(21) Appl. No.: 16/265,810

(22) Filed: Feb. 1, 2019

Related U.S. Application Data
(60) Provisional application No. 62/626,126, filed on Feb. 4, 2018.
(60) Provisional application No. 62/790,267, filed on Jan. 9, 2019.
(60) Provisional application No. 62/792,033, filed on Jan. 14, 2019.

(51) Int. Cl. G11C 14/00

(52) U.S. Cl. CPC G11C 14/0072; G11C 11/419; G11C 14/009; G11C 14/0081

(57) ABSTRACT

Methods and apparatus for memory cells that combine static random-access memory and non-volatile memory. In an exemplary embodiment, a memory cell is provided that includes a static random-access memory (SRAM) cell having Q and QB nodes and a non-volatile memory (NVM) array having a plurality of NVM cells. Each NVM cell comprises a memory element and a selector. The memory cell also includes select gates that selectively couple at least one of the Q and QB nodes to the plurality of NVM cells.

### CLAIM TO PRIORITY

This application claims the benefit of priority based upon U.S. Provisional Patent Application No. 62/792,033, filed on Jan. 14, 2019, and entitled “MEMORY CELLS COMBINING SRAM AND NVM CELLS (S-NVM) SUCH AS RRAM CELLS (S-RRAM), PCM CELL (S-PCM), MRAM CELL (S-MRAM), AND FRAM CELL (S-FRAM),” which is hereby incorporated herein by reference in its entirety.

This application claims the benefit of priority based upon U.S. Provisional Patent Application No. 62/790,267, filed on Jan. 9, 2019, and entitled “MEMORY CELLS COMBINING SRAM AND NVM CELLS (S-NVM) SUCH AS RRAM CELLS (S-RRAM),” which is hereby incorporated herein by reference in its entirety.

This application claims the benefit of priority based upon U.S. Provisional Patent Application No. 62/626,126, filed on Feb. 4, 2018, and entitled “MEMORY CELLS COMBINING SRAM AND NVM CELLS,” which is hereby incorporated herein by reference in its entirety.

### FIELD OF THE INVENTION

The exemplary embodiments of the present invention relate generally to the field of semiconductors and integrated circuits, and more specifically to memory and storage devices.

### BACKGROUND OF THE INVENTION

A typical computer system includes high-speed memory, such as Static Random-Access Memory (SRAM) for high performance, and Non-Volatile Memory (NVM) for permanent data storage. For example, the computer system utilizes the SRAM to run applications with high speed and efficiency. The computer system utilizes the NVM to store data that is not needed for immediate use. Data transfers between the SRAM and the NVM are performed through one or more independent data buses. These data buses may utilize bus controllers to provide bus synchronization, data registers, line drivers and other circuitry to facilitate data transfers. Unfortunately, data transfer rates are significantly limited by the bandwidth of these data buses, which also limits system performance.

Therefore, it is desirable to have a memory structure that provides both SRAM and NVM and that overcomes the problems associated with independent databases.

### SUMMARY

In various exemplary embodiments, novel memory cell structures and associated methods are provided that integrate Static Random-access Memory (SRAM) and Non-Volatile Memory (NVM). The new cell structures are referred to generally as ‘S-NVM’ cells. The novel memory cell structure overcomes the problems associated with independent buses since each SRAM cell is coupled to a bit line of a NVM array. In this configuration, large quantity of data can be transferred between SRAM cells and NVM cells through the bit lines without using external independent data buses. This dramatically increases data transfer rates. In an embodiment, the NVM array is located on top of the SRAM array such that silicon area can be significantly reduced. In various exemplary embodiments, the NVM comprises Resistive Random-Access Memory (RRAM), Phase-Change Memory (PCM), Magnetoresistive Random-Access Memory (MRAM), or Ferroelectric Random-Access Memory (FRAM).

In an exemplary embodiment, a memory cell is provided that includes a static random-access memory (SRAM) cell having Q and QB nodes and a non-volatile memory (NVM) array having a plurality of NVM cells. Each NVM cell includes a memory element and a selector. The memory cell also includes select gates that selectively couple at least one of the Q and QB nodes to the plurality of NVM cells.

In an exemplary embodiment, a method is provided for operating a memory cell comprising a static random-access memory (SRAM) cell having Q and QB nodes and a non-volatile memory (NVM) array. The method comprises coupling at least one of the Q and QB nodes to at least one bit line, respectively, of the NVM array and setting voltage levels for selected and unselected word lines of the NVM array. The method also comprises setting a first NVM cell connected to a selected word line to a low impedance state, if a voltage differential between the selected word line and a bit line connected to the first NVM cell exceeds a first threshold level, and resetting a second NVM cell connected to the selected word line to a high impedance state, if a voltage differential between the selected word line and a bit line connected to the second NVM cell exceeds a second threshold level. The method also comprises leaving NVM cells connected to the unselected word lines unchanged.

In an exemplary embodiment, a method is provided for operating a memory cell comprising a static random-access memory (SRAM) cell having Q and QB nodes and a non-volatile memory (NVM) array. The method comprises coupling the Q node to a bit line of the NVM array, and setting voltage levels for selected and unselected word lines, wherein current flows to the Q node, if a NVM cell connected a selected word line is in a low impedance state. The method also comprises setting the Q node of the SRAM cell to a data value of ‘1’ if the current flows.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1A shows an exemplary embodiment of an S-NVM cell structure that comprises an SRAM cell and a non-volatile memory array.

FIG. 1B shows an exemplary embodiment of a circuit that implements the cell structure shown in FIG. 1A.

FIGS. 1C-D show exemplary embodiments of RRAM cells.

FIG. 1E shows an exemplary embodiment of a circuit that implements the cell structure shown in FIG. 1A.

FIG. 1F shows an exemplary embodiment of a circuit that implements the cell structure shown in FIG. 1A and has only one node (Q) of the SRAM cell is connected to the NVM array.

FIG. 2A show an exemplary embodiment of a RRAM cell structure that includes a diode type selector.

FIG. 2B shows an exemplary embodiment of a graph showing a current-to-voltage (I-V) curve that illustrates SET and RESET operations of a RRAM cell with a diode type selector.

FIGS. 2C-D shows an exemplary embodiment of a circuit that implements an S-RRAM cell and illustrates a write operation from an SRAM cell to an RRAM cell in a NVM array.

FIG. 2E shows an exemplary embodiment of a circuit that implements an S-RRAM cell and illustrates a read operation from an RRAM cell of the NVM array to an SRAM cell.

FIG. 2F shows an exemplary alternative circuit to the circuit shown in FIG. 2C and illustrates additional embodiments of read and write operations.

FIG. 2G shows an exemplary embodiment of a circuit that implements an S-RRAM cell and that eliminates the need for the latch to use high voltage devices.

FIG. 2H illustrates an exemplary embodiment of bias conditions to set or reset a block or the entire RRAM array for use with the cell structures shown in FIGS. 2C-E.

FIG. 2I shows an exemplary embodiment of a circuit that is an alternative embodiment of the circuit shown in FIG. 2C.

FIG. 2J shows an exemplary embodiment of a circuit that is an alternative embodiment of the circuit shown in FIG. 2C.

FIG. 2K shows an exemplary embodiment of a circuit that is an alternative embodiment of the circuit shown in FIG. 2C.

FIG. 2L shows an exemplary embodiment of an MRAM cell structure.

FIG. 2M shows an exemplary embodiment of an equivalent circuit of the MRAM cell structure shown in FIG. 2L.

FIG. 2N shows an exemplary embodiment of a graph showing a current-to-voltage (I-V) curve that illustrates SET and RESET operations of an MRAM cell.

FIG. 2O shows an exemplary embodiment of a PCM cell structure.

FIG. 2P shows an exemplary embodiment of an equivalent circuit of the PCM cell structure shown in FIG. 2O.

FIG. 2Q shows an exemplary embodiment of a graph showing curves for SET and RESET operations for PCM cells, such as the PCM cell shown in FIG. 2O.

FIG. 2R shows an exemplary embodiment of a FRAM cell structure.

FIG. 2S shows an exemplary embodiment of an equivalent circuit of the FRAM cell structure shown in FIG. 2R.

FIG. 2T shows an exemplary embodiment of a graph that shows curves for operations to write ‘0’ and ‘1’ in FRAM cells.

FIG. 3A shows an exemplary embodiment of a circuit that is based on the circuit shown in FIG. 2I.

FIG. 3B shows an exemplary embodiment of a circuit that implements an S-NVM cell.

FIG. 3C shows an exemplary embodiment of a circuit that implements an S-NVM cell.

FIG. 3D shows an exemplary embodiment of a circuit that implements an S-NVM cell.

FIG. 3E shows a top view of an embodiment of large S-NVM array that comprises eight array units as shown in FIG. 3D.

FIG. 3F shows another exemplary embodiment of an array unit.

FIGS. 4A-C show exemplary embodiments of the 3D NVM array structures for use with large S-NVM arrays.

FIG. 5A shows an exemplary embodiment of a circuit that implements a 3D S-NVM array unit.

FIGS. 5B-C show exemplary embodiments of the 3D NVM array structures.

FIG. 6A shows an exemplary embodiment of a circuit that implements a 3D S-NVM array unit.

FIGS. 6B-C show exemplary embodiments of RRAM cells for use as the NVM cells shown in FIG. 6A.

FIG. 7A shows an exemplary embodiment of a circuit that implements a 3D S-NVM array unit.

FIG. 7B shows an exemplary embodiment of an equivalent circuit of a bit string shown in FIG. 7A.

FIGS. 7C-E show exemplary embodiments of cell structures for use as the NAND flash memory cell shown in FIG. 7A.

FIG. 8 shows an exemplary embodiment of method for transferring data from an SRAM cell to a NVM cell.

FIG. 9 shows an exemplary embodiment of method for transferring data from an SRAM cell to a NVM cell.

FIG. 10 shows an exemplary embodiment of method for transferring data from a NVM cell to an SRAM cell.

### DETAILED DESCRIPTION

Exemplary embodiments of the present invention are described herein in the context of novel memory cell structures and associated methods that integrate Static Random-access Memory (SRAM) and Non-Volatile Memory (NVM).

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

In various exemplary embodiments, S-NVM cell structures and associated methods are disclosed. In one embodiment, an SRAM cell is combined with Resistive Random-Access Memory (RRAM) cells to form an ‘S-RRAM’ cell. In another embodiment, an SRAM cell is combined with Phase-Change Memory (PCM) cells to form an ‘S-PCM’ cell. In another embodiment, an SRAM cell is combined with Magnetoresistive Random-Access Memory (MRAM) cells to form an ‘S-MRAM’ cell. In still another embodiment, an SRAM cell is combined with Ferroelectric Random-Access Memory (FRAM) cells to form an S-FRAM′ cell. It also should be noted that the S-NVM cell structures are not limited to the above cell structures since other types of NVM cells may be utilized to form additional types of S-NVM cells.

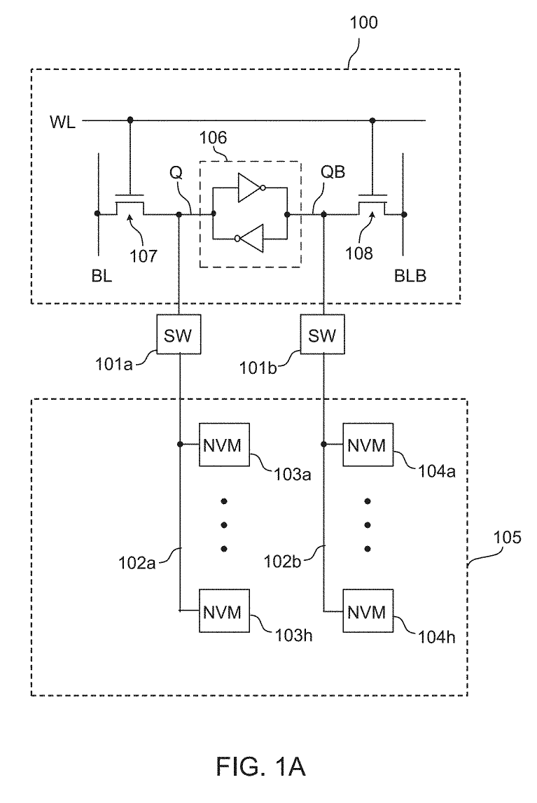

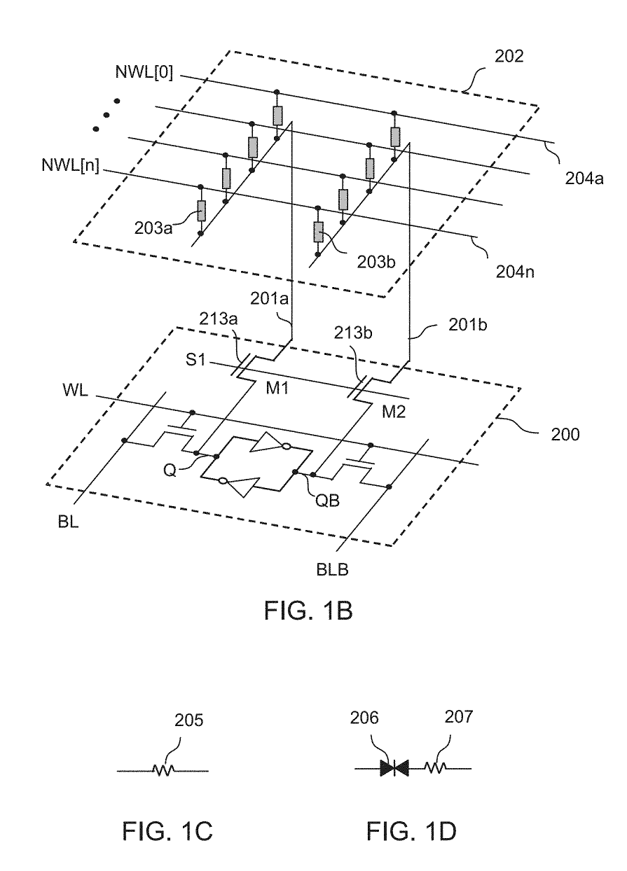

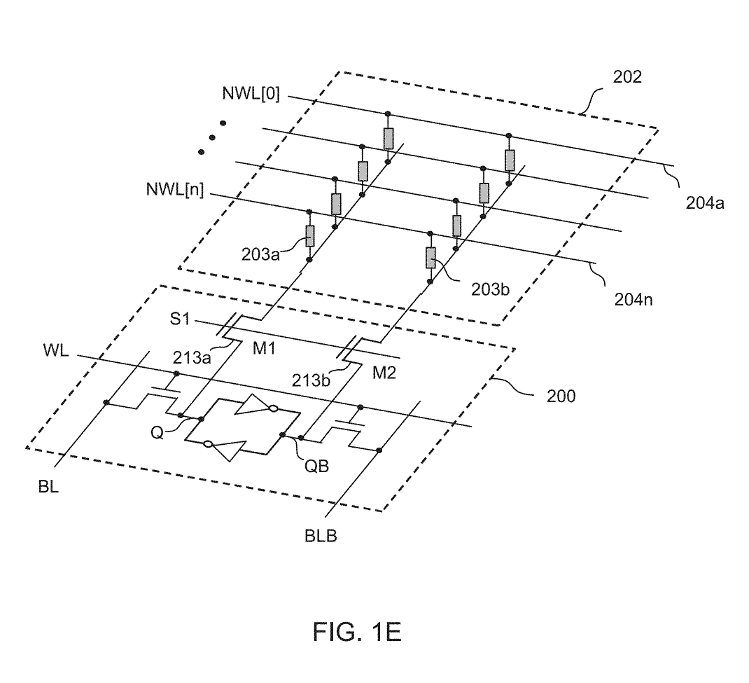

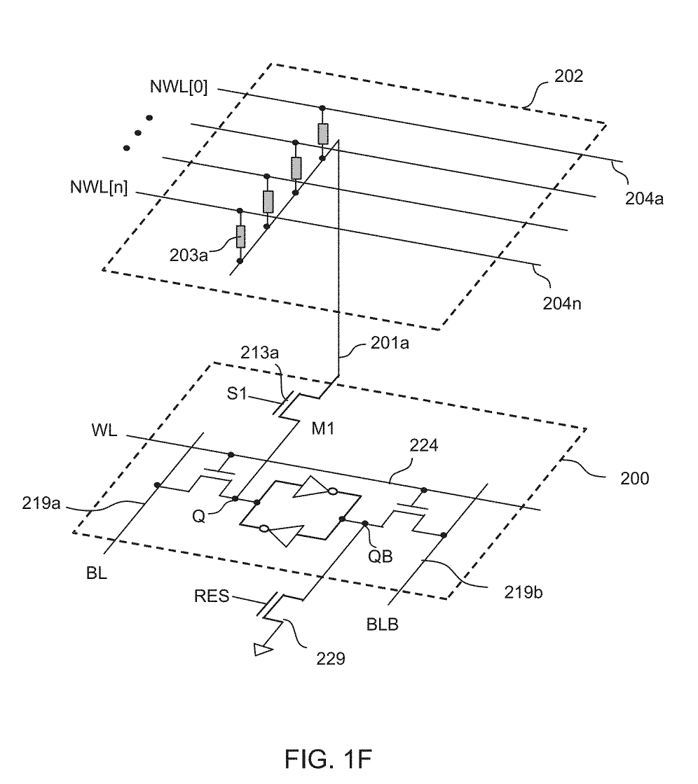

FIG. 1A shows an exemplary embodiment of an S-NVM cell structure that comprises an SRAM cell 100 and a non-volatile memory array 105. In an embodiment, the SRAM cell 100 comprises latch 106 and transistors 107 and 108. The transistor 107 couples a bit line (BL) to a Q node of the latch 106, and the transistor 108 couples a complement of the BL (e.g., bit line bar (BLB) to a QB node of the latch 106.

The SRAM cell's storage nodes Q and QB are connected to bit lines 102a and 102b of the NVM array 105 through the switches 101a and 101b. The bit lines 102a and 102b are connected to multiple NVM cells, such as NVM cells 103a-h and NVM cells 104a-h, respectively. In various exemplary embodiments, an S-NVM array is formed that comprises multiple instances of the NVM cell structure 105 to form a high-density array.

During operation, the switches 101a and 101b are turned off to isolate the SRAM cell 100 from the NVM array 105. A computing system, CPU, or other entity may read and write the SRAM cell 100 using high speed read and write operations, for instance, as used with conventional SRAM. To transfer the data stored in the SRAM cell 100 to the NVM array 105, the switches 101a and 101b are turned on to pass the data of the SRAM cell's Q and QB nodes to the NVM array's bit lines 102a and 102b. A write condition is applied to selected NVM cells to write the data into those cells.

To transfer data stored in the NVM array 105 to the SRAM cell 100, the switches 101a and 101b are turned on to connect the NVM array's bit lines 102a and 102b to the Q and QB nodes of the SRAM cell 100. A read condition is applied to selected NVM cells to read the data and transfer the data to the Q and QB nodes of the SRAM cell 100 through the NVM bit lines 102a and 102b.

The above-described operations between the SRAM cell 100 and NVM array 105 can be performed for multiple SRAM cells or an entire SRAM array in parallel. This novel cell structure allows large amounts data to be directly transferred between SRAM cells and a NVM array without using an external data bus, and therefore significantly increases the data transfer rate and reduces data latency.

In exemplary embodiments, the NVM cells comprises any type of NVM technology suitable for the process, such as NOR flash memory, NAND flash memory, Resistive Random-Access Memory (RRAM), Phase-Change Memory (PCM), Ferroelectric Random-Access Memory (FRAM), and Magnetoresistive Random-Access Memory (MRAM).

FIG. 1B shows an exemplary embodiment of a circuit that implements the cell structure shown in FIG. 1A. The circuit comprises SRAM cell 200 and NVM array 202. In an exemplary embodiment, NVM cells, such as cell 203a and cell 203b in the NVM array 202, are formed by using only passive devices, such as variable resistors, variable capacitors, and diodes. In one embodiment, the NVM array 202 is located in the back-end of line (BEOL), such as on metal layers. For example, in fabrication, the transistors and devices on the substrate are called front-end of line (FEOL). The contacts, insulating layers, metal levels, and bonding sites for chip-to-package connections are called back-end of line (BEOL). This allows the NVM array 202 to be placed on top of the SRAM cell 200, and therefore significantly reduces the silicon area that is utilized. In other embodiments, the NVM array 202 may be located on another die, chip, or wafer and connected to the SRAM cell 100 using any 3D integration process, such as copper pillar, micro-bump, Cu—Cu bond, through-silicon via (TSV), and/or any other suitable technologies. It should also be noted that although the SRAM cell 200 utilizes a six transistor (6T) SRAM configuration plus two pass gates 213a and 213b, in other embodiments, the SRAM cell 200 may be implemented with a four-transistor (4T) SRAM configuration and two pull-up resistors to replace two PMOS devices of the latch.

The NVM array 202 may contain multiple NVM cells, such as shown at 203a and 203b. The transistors M1 213a and M2 213b are switches that connect the SRAM cell's data storage nodes, Q and QB, to the NVM array's bit lines 201a and 201b. The transistors M1 213a and M2 213b (switches) may be implemented by using NMOS, PMOS, or a PMOS-NMOS pair. The NVM array 202 also comprises word lines 204a-n. When the switches M1 213a and M2 213b are turned on, the data stored in the SRAM cell's Q and QB nodes may be written to or read from the NVM cells (such as cells 203a and 203b) on a selected word line, such as word line 204n.

In various exemplary embodiments, the NVM cells of the NVM array 202 may be RRAM cells, PCM cells, MRAM cells, FRAM cells, or other suitable NVM cell type. For simplicity and clarity, the following description is provided using RRAM technology for the cells of the NVM array. However, it should be understood that any other types of NVM cells can be used and are within the scope of the invention.

FIGS. 1C-D show exemplary embodiments of RRAM cells. In FIG. 1C, the RRAM cell 205 comprises only a resistive layer (or element). In FIG. 1D, the RRAM cell comprises a variable resistive element 207 and a selector 206. The selector may have unidirectional or bidirectional threshold behavior, such as provided by a diode, Schottky diode, or other material having threshold behavior. During operation, the selector may prevent sneak current leakage paths (current leakage) through unselected word lines and bit lines.

FIG. 1E shows an exemplary embodiment of a circuit that implements the cell structure shown in FIG. 1A. Although it may be desired to have the NVM array 202 located on top of the SRAM cell to reduce silicon area, if the process does not support that type of structure, the NVM array 202 can be located on the same substrate as the SRAM 200, as shown in FIG. 1E.

It should be noted that although the embodiment in FIG. 1B shows that both the Q and QB nodes of the SRAM cell 200 are connected to the RRAM array 202, it is possible to connect only one node of the SRAM cell to the RRAM array as illustrated in the next figure.

FIG. 1F shows an exemplary embodiment of a circuit that implements the cell structure shown in FIG. 1A and has only one node (Q) of the SRAM cell is connected to the NVM array. In this embodiment, when transferring data from the NVM cells to the SRAM cell, because the NVM cells only drives one side of the SRAM cell, the SRAM cell may need to be reset before the transfer operation. A reset of the SRAM cell 200 can be performed by using the word line 224, bit line (BL) 219a and the bit line bar (BLB) 219b to perform a reset like in a traditional SRAM. In another embodiment, a reset device 229 is added to either of the Q or QB nodes to reset the SRAM cell.

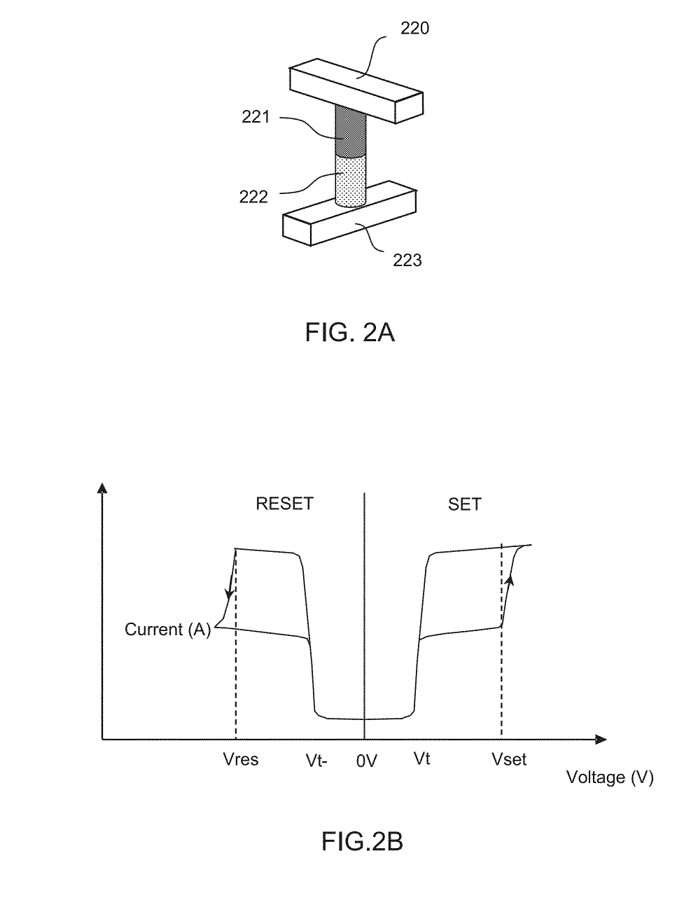

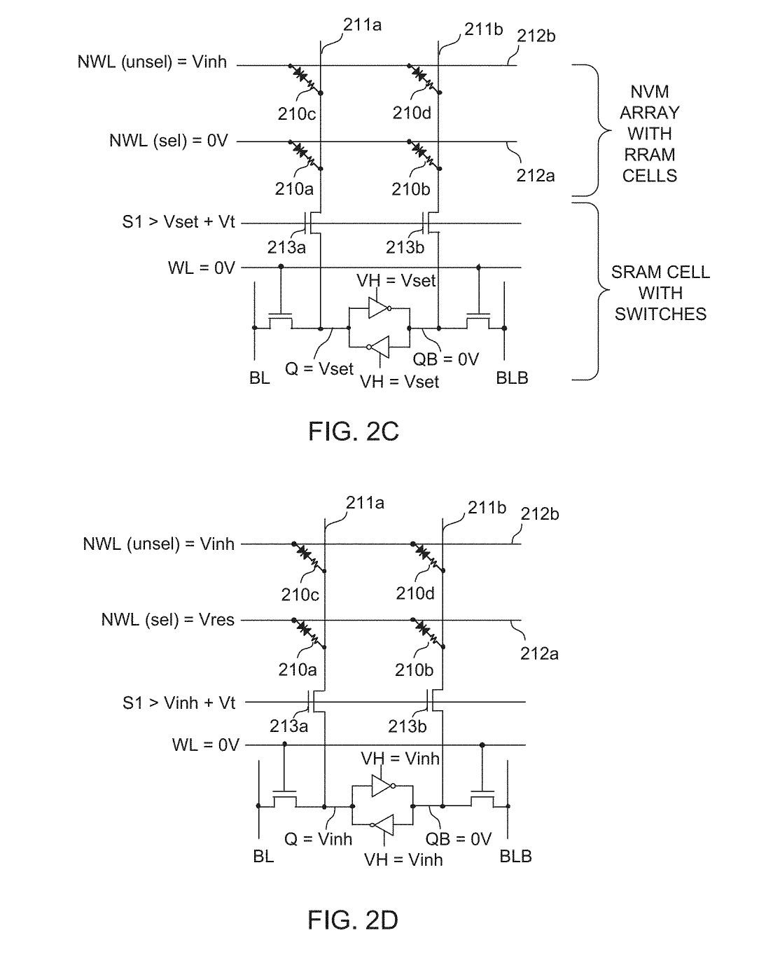

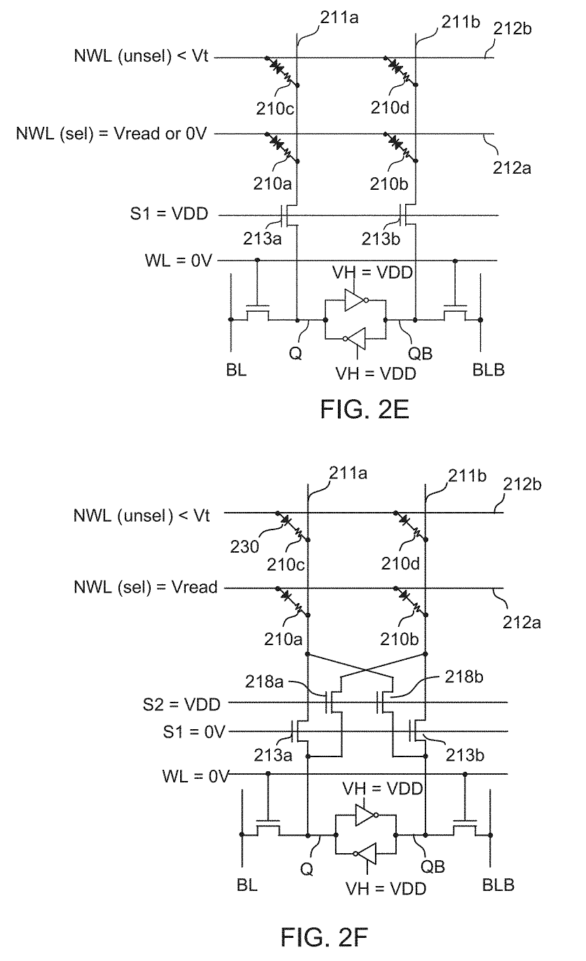

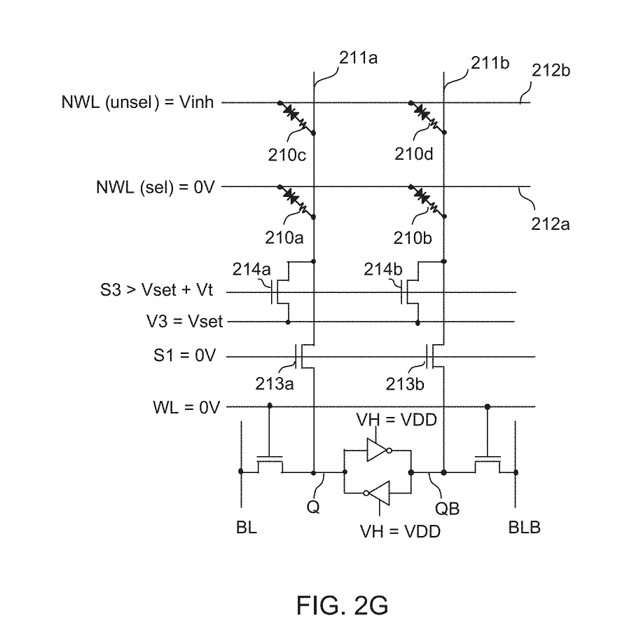

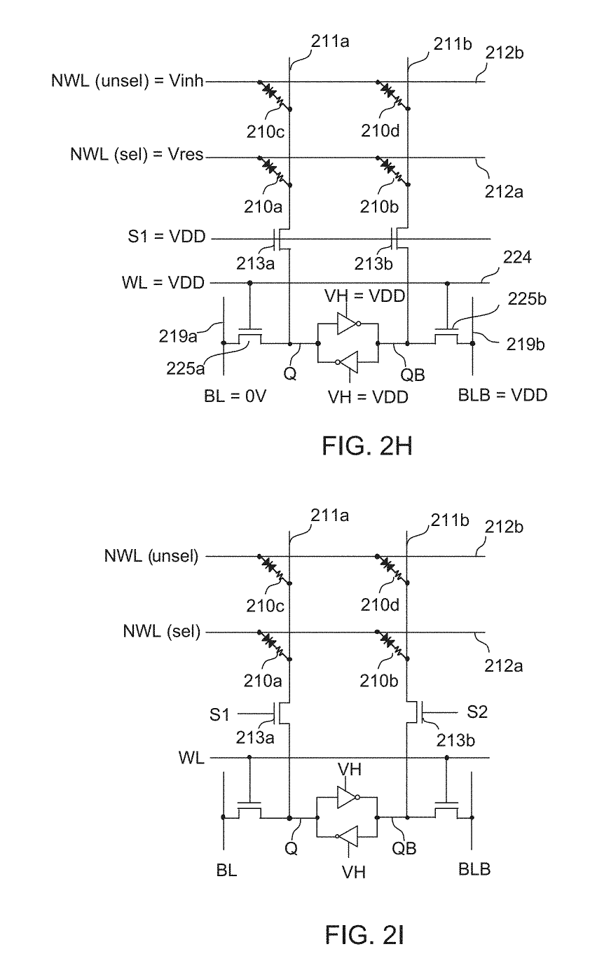

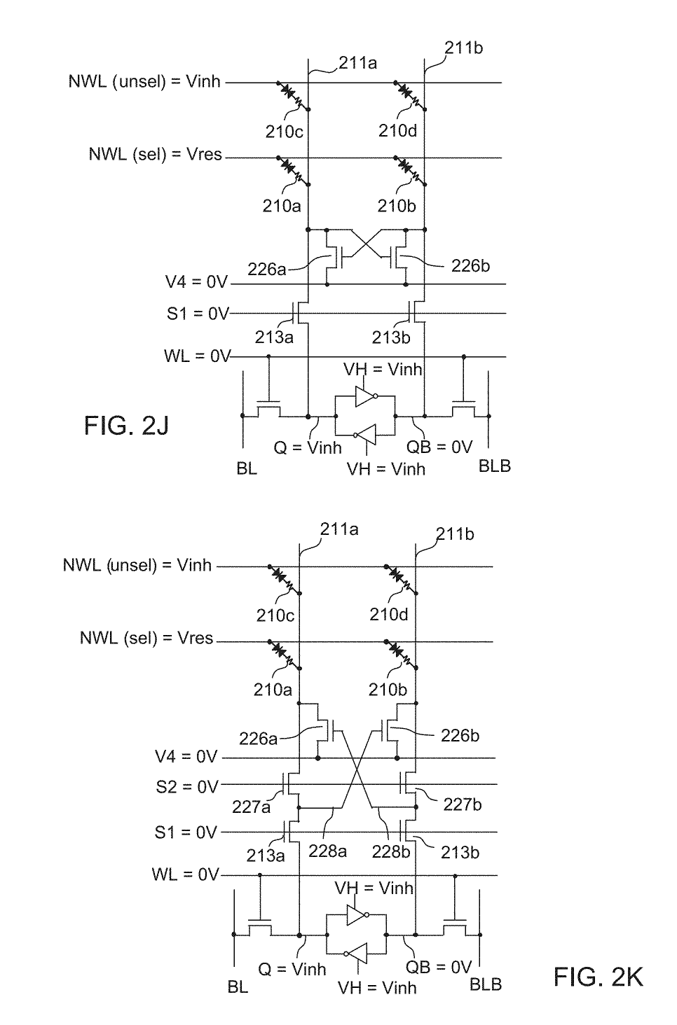

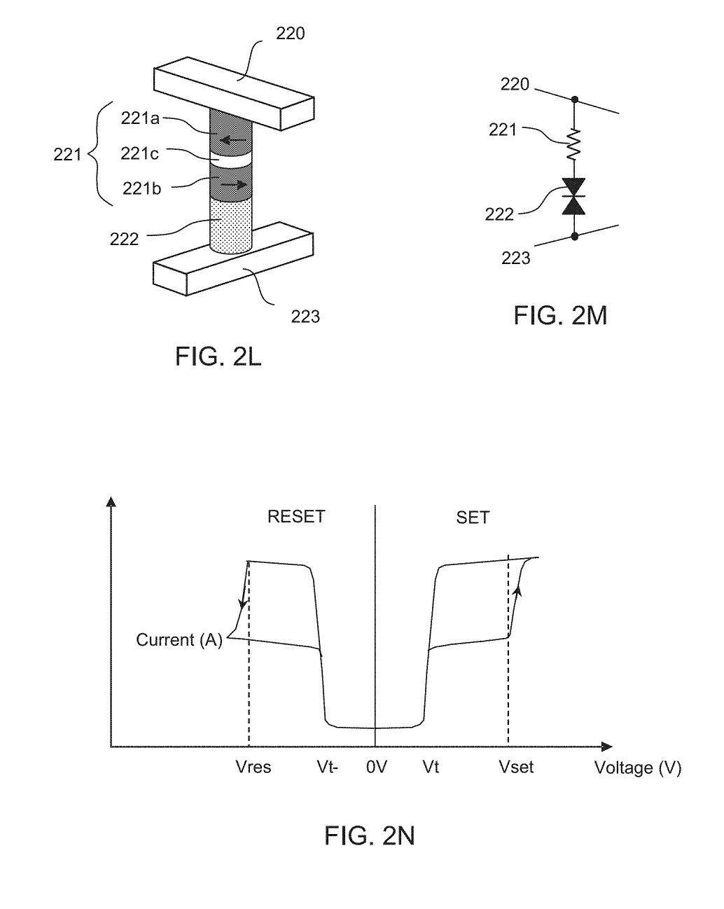

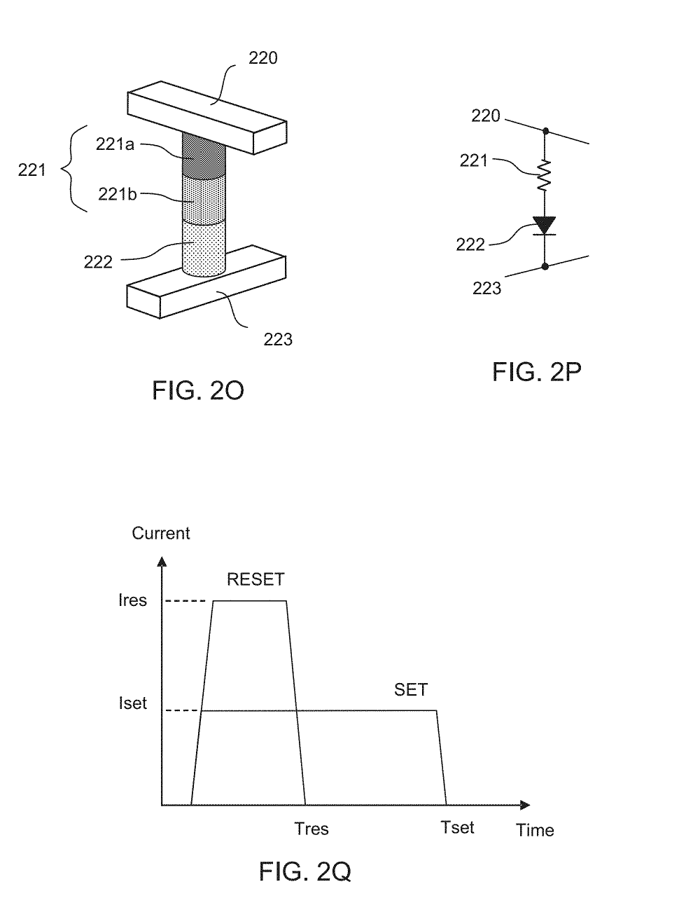

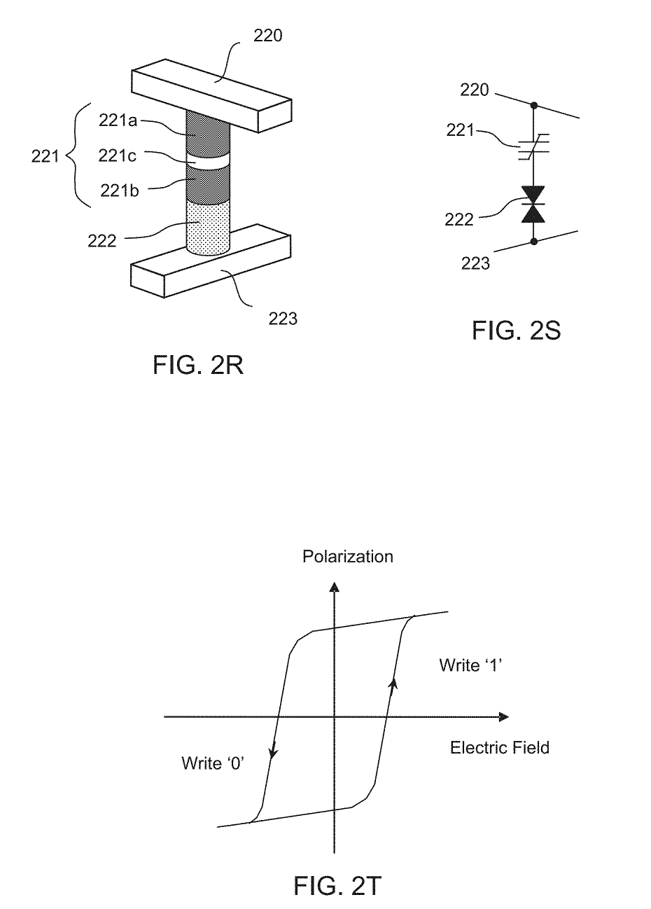

FIG. 2A show an exemplary embodiment of a RRAM cell structure that includes a diode type selector. The RRAM cell structure comprises a top metal line 220 that forms a word line and a bottom metal line 223 that forms a bit line. The RRAM cell structure also comprises a variable resistive element 221 and a selector 222, such as a diode or other material with threshold behavior. The positions of the variable resistive element 221 and the selector 222 may be exchanged, and thus the resistive element 221 will be coupled to the bit line 223 side and the selector 222 will be coupled to the word line 220 side.

In various exemplary embodiments, the word line 220 and the bit line 223 comprises special metals, such as titanium (Ti), tantalum (Ta), copper (Cu), platinum (Pt), tungsten (W), or ruthenium (Ru). The resistive element 221 comprises metal-oxide, such as HfOx, NbOx, TiOx, TaOx, ZrOx, SiOx, or AlOx. The selector 222 comprises a silicon diode, Schottky diode, Tunnel barrier based selector, mixed ionic-electron conduction selector or special metal-oxide that has threshold behavior, such as NbOx, ZrOx, TiOx, or CuGeS. Since the RRAM cell shown in FIG. 2A only uses passive devices, it may be placed on top of the SRAM cell as shown in FIG. 1B to reduce silicon area.

FIG. 2B shows an exemplary embodiment of a graph showing a current-to-voltage (I-V) curve that illustrates SET and RESET operations of an RRAM cell with a diode type selector. In the I-V curve, Vt and Vt− are the threshold voltage of the selector. When the voltages across the RRAM cell is more positive than Vt, or more negative than Vt−, the selector will be turned on to conduct current. If the voltage is less positive than Vt or less negative than Vt−, the selector will be turned off. Vset and Vres are the minimum voltages across the RRAM cell. In the other words, the voltage difference between the word line 220 and bit line 223 causes SET and RESET operations. The SET and RESET operations decrease and increase the cell's resistance (e.g., of the resistive element 221), respectively.

In exemplary embodiments, the SET or RESET operations are determined by the polarity of the voltages applied to the word line and bit line of the selected cell. In an exemplary embodiment, the cell structure shown in FIG. 2A is asymmetrical. When the bit line and word line designations are reversed (or flipped), the SET and RESET operation are reversed as well.

FIGS. 2C-D show exemplary embodiments of a circuit that implements an S-RRAM cell and illustrates a write operation from an SRAM cell to an RRAM cell in an NVM array. FIG. 2C shows a write operation to write a ‘1’ from the node Q to the RRAM cell 210a. It will be assumed that the RRAM cells 210 have a Vt that is 1V, Vset is 2V and Vres is 2V. Referring to FIG. 2C, during a write RRAM operation, the power lines (VH) of the SRAM's latch are supplied with a voltage higher than Vset, such as 2.5V for example. It will be assumed that the SRAM cell's Q and QB nodes store data ‘1’ and ‘0’, respectively. A control signal (S1) of the switches 213a and 213b is supplied with a voltage higher than [Vset+Vt], such as 3.5V, to pass Vset and 0V from the Q and QB nodes to the bit lines 211a and 211b, respectively. A selected NVM word line, NWL (sel) 212a, and unselected NVM word line, NWL (unsel) 212b, are supplied with 0V and an inhibit voltage (Vinh) such as 1V, respectively. As a result, the voltage difference across the RRAM cell 210a will set the resistance of the cell 210a to a low impedance state. Meanwhile, the RRAM cells 210b, 210c, and 210d will not be set due to the fact that the voltage differences across these cells are not high enough.

FIG. 2D shows a write operation to write a “0” from the node QB to the RRAM cell 210b. The power lines (VH) of the SRAM's latch are supplied with an inhibit voltage (Vinh), such as 1V for example. The control signal (S1) of the switches 213a and 213b is supplied with a voltage higher than [Vinh+Vt], such as 2V, to pass Vinh and 0V from the Q and QB nodes to the bit lines 211a and 211b, respectively. The selected NWL 212a and unselected NWL 212b are supplied with Vres and an inhibit voltage (Vinh), such as 2.5V and 1V, respectively. This bias condition will reset the RRAM cell 210b to high resistance. Meanwhile, the RRAM cells 210a, 210c, and 210d will not be reset due to the fact that the voltage differences across these cells are not high enough.

In FIGS. 2C-D, whether the RRAM cells 210a and 210b perform RESET or SET operations is dependent to the RRAM cell's structure. In an exemplary embodiment, the cell structure of the RRAM cells shown in FIGS. 2C-D are asymmetrical. When the bit line and word line designations are reversed (or flipped), the SET and RESET operations are reversed as well. Under these conditions, the bias conditions in FIG. 2C will cause the RRAM cell 210a to be reset to high resistance and the bias condition in FIG. 2D will cause the RRAM cell 210b to be set to low resistance.

FIG. 2E shows an exemplary embodiment of a circuit that implements an S-RRAM cell and illustrates an operation to read data from an RRAM cell of the NVM array and transfer the data to an SRAM cell. For example, the operation reads data from RRAM cell 210a and transfers the data to the node Q of the SRAM cell. During the RRAM read operation, the VH of the SRAM latch is set to VDD. The control signal (S1) of the switches 213a and 213b is supplied with VDD. The selected NWL 212a is supplied with a read voltage (Vread) higher than Vt of the RRAM cells, such as VDD. Because the RRAM cell 210a is set to low resistance by the operation shown in FIG. 2C, current will flow from the selected NWL 212a through the RRAM cell 210a to the bit line 211a. Meanwhile, due to the fact that the RRAM cell 210b is reset to a high resistance by the operation shown in FIG. 2D, current will not flow through the RRAM cell 210b. As a result of the current flow, the voltage of the Q node will be pulled up and flips the data of the Q node of the SRAM cell to ‘1’.

In another embodiment, it will be assumed that the RRAM cells' structure is reversed (or flipped) with respect to the word line and bit line. When the bit line and word line designations are reversed (or flipped), the SET and RESET operations are reversed as well. Under these conditions, the bias condition described with reference to FIG. 2C will reset the RRAM cell 210a to a high resistance, and the bias condition described with reference to FIG. 2D will set the RRAM cell 210b to low resistance. Therefore, during the read RRAM operation shown in FIG. 2E, the selected NVM word line 212a can be supplied with a low voltage, such as 0V. This bias condition will cause current flowing from the bit line 211b through the RRAM cell 210b to the selected NWL 212a. Meanwhile, due to the fact that the RRAM cell 210a has high resistance, current will not flow through the RRAM cell 210a. As a result of the current flow, the voltage of the node QB will be pulled low and will flip the data in the Q node of the SRAM cell to ‘1’.

During the RRAM read operation, the unselected word line 212b can be supplied with a voltage to make the word line and bit line voltage difference lower than Vt, such as VDD/2 for example, if VDD is lower than 2V. This will turn off the selector of the unselected RRAM cells 210c and 210d, and thus no current will flow through the unselected cells. After the data is read from the RRAM cells to the SRAM cell, the signal S1 may go to 0V to turn off the pass gates 213a and 213b. Then, the system may read and write the SRAM cells as traditional SRAM cells.

FIG. 2F shows an exemplary alternative circuit to the circuit shown in FIG. 2C and illustrates additional embodiments of read and write operations. This embodiment assumes that the structure of the NVM cells 210 has a unidirectional selector 230, such as the phase-change memory (PCM) cell shown in FIGS. 2O-Q. This limits the direction of current flow so that current flows only from the NVM words lines 212a and 212b to the bit lines 211a and 211b. It will be assumed that the data of the Q and QB nodes are ‘1’ and ‘0’, respectively. During a write NVM operation, the power line (VH) of the SRAM cell is supplied with an inhibit voltage (Vinh) (not shown in FIG. 2F). This makes the voltage of the Q and QB nodes to be Vinh and 0V, respectively. The selected word line NWL (sel) 212a is supplied with Vset (not shown in FIG. 2F). This will set the NVM cell 210b to low resistance.

During a read NVM operation, the power line (VH) of the SRAM latch is supplied with VDD (as shown in FIG. 2F). The selected word line NWL (sel) 212a is supplied with Vread (as shown in FIG. 2F). Current will flow from the NWL (sel) 212a through the NVM cell 210b to bit line 211b and will pull up the QB node. This will flip the SRAM cell's Q and QB nodes to ‘0’ and ‘1’, respectively. However, this data read from the NVM cell to SRAM cell is reversed from the original data stored in the SRAM cell. To solve this problem, in this embodiment, extra transistor devices 218a and 218b are added to cross-couple the bit lines 211a and 211b. During NVM write operations, the signal (S2) is supplied with 0V to turn off the transistors 218a and 218b. The transistors 213a and 213b will pass the voltage of the Q and QB nodes to the bit lines 211a and 211b to set or reset the selected NVM cells 210a and 210b, respectively. During a NVM read operation, the signal (S1) is supplied with 0V to turn off the transistors 213a and 213b. The signal (S2) is supplied with VDD to turn on to the transistors 218a and 218b. This causes the data read from the NVM cells 210a and 210b to be reversely loaded to the QB and Q nodes, respectively.

FIG. 2G shows an exemplary embodiment of a circuit that implements an S-RRAM cell and that eliminates the need for the latch of the SRAM to use high voltage devices. For example, as shown in FIG. 2C, the bias condition requires Vset or Vres to be applied to the SRAM latch's power supply VH. This may require the latch to use high voltage devices, if Vset or Vres are higher than VDD. This may reduce the speed of the SRAM cell.

In the embodiment shown in FIG. 2G, extra devices 214a and 214b are added to the bit lines 211a and 211b as shown. During set operations, a voltage source (V3) is applied to Vset. The signal (S3) is supplied with a voltage higher than [Vset+Vt] to pass Vset from (V3) to the bit lines 211a and 211b. The selected NWL 212a is supplied with 0V. This will set both of the RRAM cells 210a and 210b to low resistance. Meanwhile, the signal (S1) is supplied with 0V to turn off transistors 213a and 213b.

After the RRAM cells 210a and 210b are set, the bias condition shown in FIG. 2D can be applied to reset the RRAM cell 210b to high resistance. It should be noted that for the conditions in FIG. 2D, since the SRAM latches' voltage VH is supplied with Vinh, which may be lower than VDD, the SRAM may use low voltage devices. This may enhance the speed and performance of the SRAM cell.

In another embodiment, it will be assumed that the NWL 212a and 212b are a second material and the bit lines 211a and 211b are a first material that are the reverse what is described above. The bias condition in FIG. 2G will reset the RRAM cells 210a and 210b to a high resistance, and the bias condition in FIG. 2D will set the RRAM cells 201b to a low resistance.

It should be noted that for the bias condition shown in FIG. 2G, multiple NVM word lines or all the NVM word lines can be supplied with 0V to set or reset a block or the entire RRAM array. In another embodiment, the power line (V3) is supplied with 0V. The signal (S3) is supplied with VDD to pass 0V from (V3) to the bit lines 211a and 211b. The selected NWM word lines can be supplied with Vset or Vres to set or reset the RRAM cells.

FIG. 2H illustrates an exemplary embodiment of bias conditions to set or reset a block or the entire RRAM array for use with the cell structures shown in FIGS. 2C-E. In this embodiment, multiple selected NVM word lines, such as 212a are supplied with Vset or Vres. The signal (S1) is supplied with VDD to turn on transistors 213a and 213b. The word line 224 of the SRAM cell is supplied with VDD to turn on transistors 225a and 225b. The operation comprises two steps. In a first step, all the SRAM cells' bit lines (e.g., BL 219a and BLB 219b) are supplied with 0V and VDD, respectively. This will pass 0V to the SRAM cells' Q node and the RRAM bit line 211a to set or reset the selected RRAM cells on the bit line. In a second step, all the SRAM cells' bit lines (e.g., BL 219a and BLB 219b) are supplied with VDD and 0V, respectively. This will pass 0V to all the SRAM cells' QB node and the RRAM bit lines 211b to set or reset the selected RRAM cells on the bit lines.

In another embodiment, all the SRAM cells' BL and BLB may be supplied with 0V together. This will pass 0V to both the Q and QB nodes and the RRAM bit lines 211a and 211b to set or reset all the selected RRAM cells. In this embodiment, to avoid conflicts, the SRAM cells' power line (VH) can be floating or supplied with 0V.

FIG. 2I shows an exemplary embodiment of a circuit that is an alternative embodiment of the circuit shown in FIG. 2C. In this embodiment, the transistors 213a and 213b are connected to different control signals (S1) and (S2). The signals (S1) and (S2) can be selectively turned on to allow the SRAM cell's data in the Q and QB nodes to be written to or read from RRAM cells 210a or 210b independently. This allows the RRAM cells 210a and 210b to store different data, and thus the data capacity of the RRAM array is doubled. For example, the first data may be written to the SRAM cell, and then written from the Q node to RRAM cell 210a by turning on (S1) and transistor 213a. The second data may be written to the SRAM cell, and then written from the QB node to the RRAM cell 210b by turning (S2) and transistor 213b. It should be noted that all the previously described operations in FIG. 2C-H may be applied to this embodiment to set, reset, or read a single side of the RRAM cells.

FIG. 2J shows an exemplary embodiment of a circuit that is an alternative embodiment of the circuit shown in FIG. 2C. In this embodiment, two extra transistors 226a and 226b are connected to the bit lines 211a and 211b. During set or reset operation, the voltage source (V4) is supplied with 0V. The signal (S1) is supplied with a voltage to turn on transistors 213a and 213b to pass the voltages of the Q and QB nodes to the bit lines 211a and 211b. After that, (S1) is supplied with 0V to turn off transistors 213a and 213b, and the voltages of bit lines 211a and 211b are maintained by the transistors 226a and 226b. The voltage of the bit line 211a will turn on the transistor 226b to apply 0V from the voltage source (V4) to the bit line 211b. This will supply the reset current of the RRAM cell 210b. On the other hand, the voltage of the bit line 211b will turn off the transistor 226a. Using this method, the SRAM cell is isolated from the bit lines 211a and 211b during the set and reset operation. Therefore, the SRAM cell may be used for the next read/write cycle, while the RRAM cells are set or reset.

FIG. 2K shows an exemplary embodiment of a circuit that is an alternative embodiment of the circuit shown in FIG. 2C. This embodiment is similar to the embodiment shown in FIG. 2J except that two more transistors 227a and 227b are added. During set or reset operation, (S2) is supplied with 0V to turn off the transistors 227a and 227b. The control signal (S1) is supplied with a voltage to turn on the transistors 213a and 213b to pass the voltages of Q and QB nodes to the nodes 228a and 228b, and then (S1) is supplied with 0V to turn off the transistors 213a and 213b. Therefore, the voltages of Q and QB nodes are trapped in the nodes 228a and 228b. The voltage of the nodes 228a will turn on the transistor 226b to supply 0V from the voltage source (V4) to the bit line 211b to reset the RRAM cell 210b, while the voltage of the node 228b will turn off the transistor 226a. By using this method, the SRAM cell may be used for the next read/write cycle, while the RRAM cells are set or reset.

Although the embodiments in FIGS. 2C-K shows both the Q and QB nodes of the SRAM cell connected to the NVM bit lines 211a and 211b, as shown in FIG. 1F, the SRAM cell can connect only one node, either Q or QB, to the NVM bit line. The operations and conditions described with respect to FIGS. 2C-K may be modified accordingly. These modifications are within the scope of the exemplary embodiments.

FIG. 2L shows an exemplary embodiment of an MRAM cell structure. For example, as described with respect to FIG. 1B, the NVM cells comprise MRAM cells, PCM cells, or FRAM cells. The MRAM cell structure shown in FIG. 2L is similar to RRAM cell shown in FIG. 2A except that the non-volatile memory element 221 contains three layers (e.g., 221a to 221c). Layers 221a and 221b are magnetic layers, such as CoFeB. Layer 221a is a ‘free layer’ and layer 221b is a ‘fixed layer’ or ‘reference layer’. For example, the fixed layer is a permanent magnet set to a particular polarity. The free layer's magnetization can be changed with respect to the polarity of the fixed layer to store data ‘1’ or ‘0’. Layer 221c is a barrier layer such as MgO. Layer 222 is a selector, such as a diode or other material with threshold behavior. It should be noted that in other embodiments of the MRAM cell structure, the positions of the free layer 221a and fixed layer 221b can be exchanged. Moreover, the positions of the memory element 221 and the selector 222 can be exchanged.

FIG. 2M shows an exemplary embodiment of an equivalent circuit of the MRAM cell structure shown in FIG. 2L. In an embodiment, the memory element 221 behaves like a variable resistor and the selector 222 behaves like a bi-directional diode.

FIG. 2N shows an exemplary embodiment of a graph showing a current-to-voltage (I-V) curve that illustrates SET and RESET operations of a MRAM cell. The X-axis shows the voltage difference between the cell's word line and bit line. In the graph, Vt and Vt− are the threshold voltages of the bi-directional selector. The voltages Vset and Vres are the minimum voltages for SET and RESET operations. When the word line to bit line voltage difference is higher than Vset, the current flowing through the memory element 221 causes the magnetization direction of the free layer 221a to be parallel to the magnetization direction of the fixed layer 221b, and thus it sets the memory element to a low resistance state. When the bit line to word line voltage is more negative than Vres, the current flows in the reverse direction and causes the magnetization direction of the free layer 221a to be anti-parallel to the magnetization direction of the fixed layer 221b, and thus it resets the memory element to a high resistance state.

FIG. 2O shows an exemplary embodiment of a PCM cell structure. This cell structure is similar to RRAM cell shown in FIG. 2A except that the non-volatile memory element 221 comprises a phase-change material layer 221a and a ‘heater’ layer 221b. The phase-change material layer 221a comprises a material, such as chalcogenide glasses or (GeSbTe) germanium-antimony-tellurium. The heater layer 221b comprises a high-resistance conductor. A selector 222 is provided that comprises a diode or other material with threshold behavior. In another embodiment of the cell structure shown in FIG. 2O, the positions of the phase-change material 221a and heater layer 221b may be exchanged. Moreover, in still another embodiment, the positions of the memory element 221 and the selector 222 may be exchanged.

FIG. 2P shows an exemplary embodiment of an equivalent circuit of the PCM cell structure shown in FIG. 2O. In the equivalent circuit, the memory element 221 behaves like a variable resistor, and the selector 222 behaves like a diode.

FIG. 2Q shows an exemplary embodiment of a graph showing curves for SET and RESET operations for PCM cells, such as the PCM cell shown in FIG. 2O. A voltage difference applied to the word line and bit line will cause current to flow through the heater layer 221b and increase the temperature of the heater layer 221b. When the current is higher than Tres, the temperature causes the phase-change material 221a to enter an amorphous state, and thus resets the memory element to a high resistance state. When the current is higher than Iset, the temperature causes the junction of the phase-change material 221a to enter a crystalline state, and thus sets the memory element to a low resistance state. For PCM cells, the set and reset currents can be applied in the same direction. Therefore, the selector 222 is unidirectional. In another embodiment, the set and reset current can be applied from the opposite directions. Then, the selector 222 is bi-directional.

FIG. 2R shows an exemplary embodiment of a FRAM cell structure. This cell structure is similar to RRAM cell shown in FIG. 2A except that the non-volatile memory element 221 contains three layers (e.g., 221a-c). The layers 221a and 221b are top and bottom electrodes that comprise material such as Pt or IrO2. The layer 221c comprises a ferroelectric film, such as lead zirconate titanate (PZT), to form a variable capacitor. A selector 222 comprises a diode or other material with threshold behavior. In another embodiment, the positions of the memory element 221 and the selector 222 are exchanged.

FIG. 2S shows an exemplary embodiment of an equivalent circuit of the FRAM cell structure shown in FIG. 2R. In the equivalent circuit, the memory element 221 behaves like a ferroelectric capacitor (e.g., variable capacitor), and the selector 222 behaves like a bi-directional diode.

FIG. 2T shows an exemplary embodiment of a graph that shows curves for operations to write ‘0’ and ‘1’ in FRAM cells. When writing ‘1’, a sufficient voltage difference is applied to the word line and bit line so that the generated electric field causes polarization reversal of the ferroelectric film 221c, and thus the capacitance is increased. When writing ‘0’, a sufficient voltage difference is applied to the word line and bit line in the reverse direction. The generated electric field causes polarization reversal of the ferroelectric film 221c, and thus the capacitance is decreased. During a read operation, a voltage is applied to the word line that will cause charge-sharing between the cell capacitance and the bit line capacitance. Therefore, the higher cell capacitance will result in higher bit line voltage. Because the voltage for writing ‘1’ and ‘0’ are applied in the reverse directions, the selector 222 can be bi-directional.

The MRAM, PCM, and FRAM cell structures shown in FIGS. 2L-T all use passive devices only, and thus they may be located on top of the SRAM cells to reduce the silicon area. In another embodiment, the MRAM, PCM, and FRAM cells shown in FIGS. 2L-T have no selector 222. This may cause leakage current for unselected cells since there is no selector to turn off the unselected cells. However, these embodiments can still operate as desired if the SRAM cell's driving current is higher than the total leakage current of the unselected cells on a bit line.

In exemplary embodiments, the combined S-NVM cells using the MRAM, PCM, and FRAM cells as shown in FIGS. 2L-T can be operated using the same or similar bias conditions as shown and described with respect to FIGS. 2C-K with minor modifications according to the characteristics of each type of cell. For simplicity and to avoid redundant description, the detailed operations of these embodiments will not be repeated here.

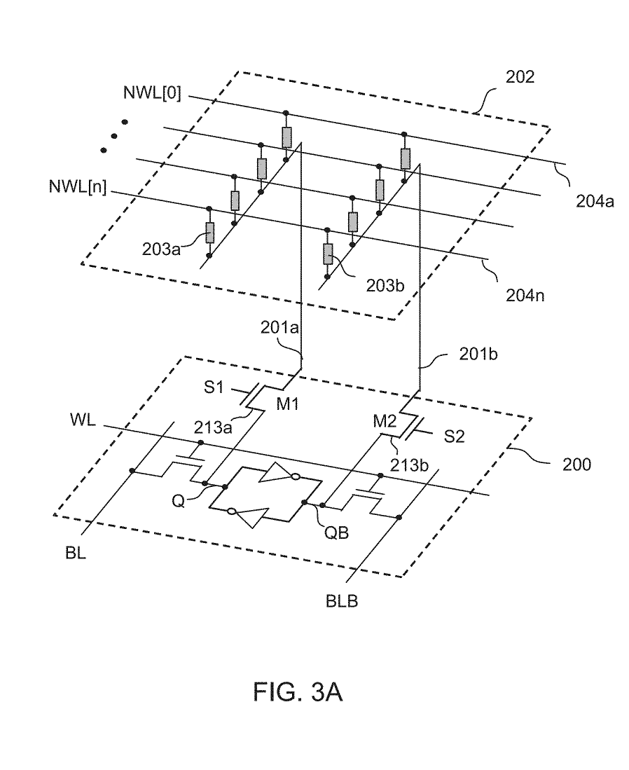

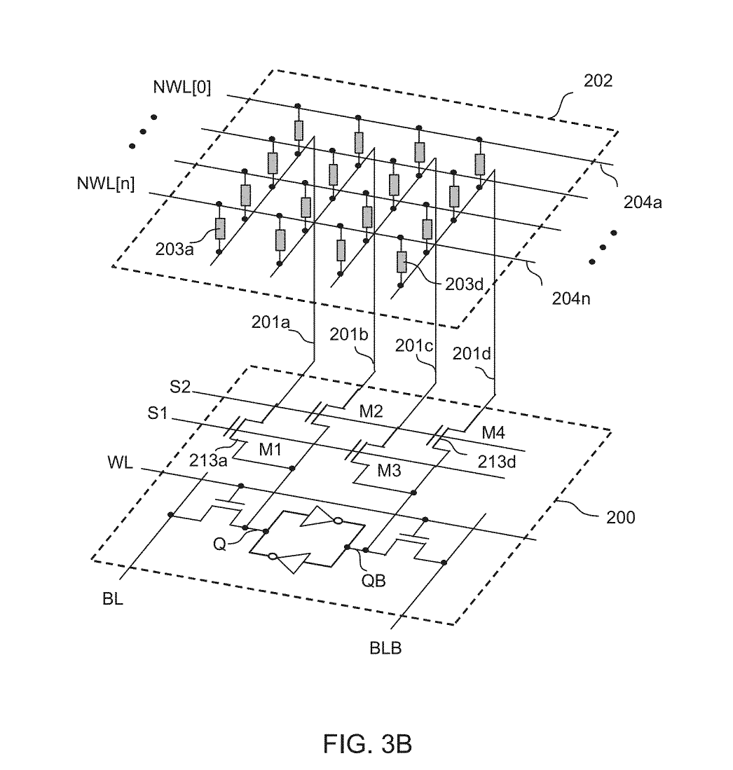

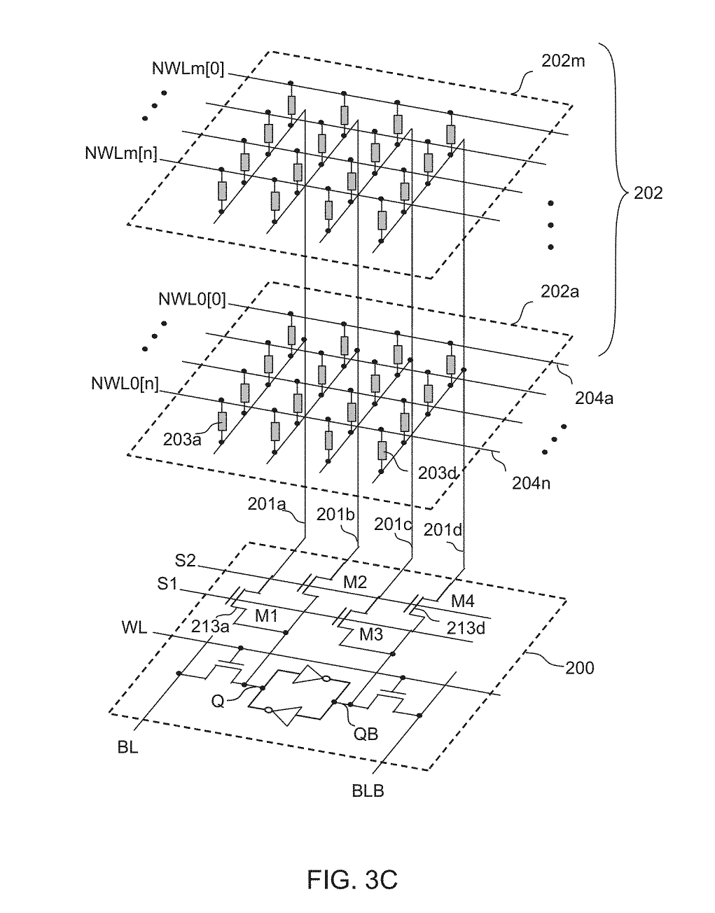

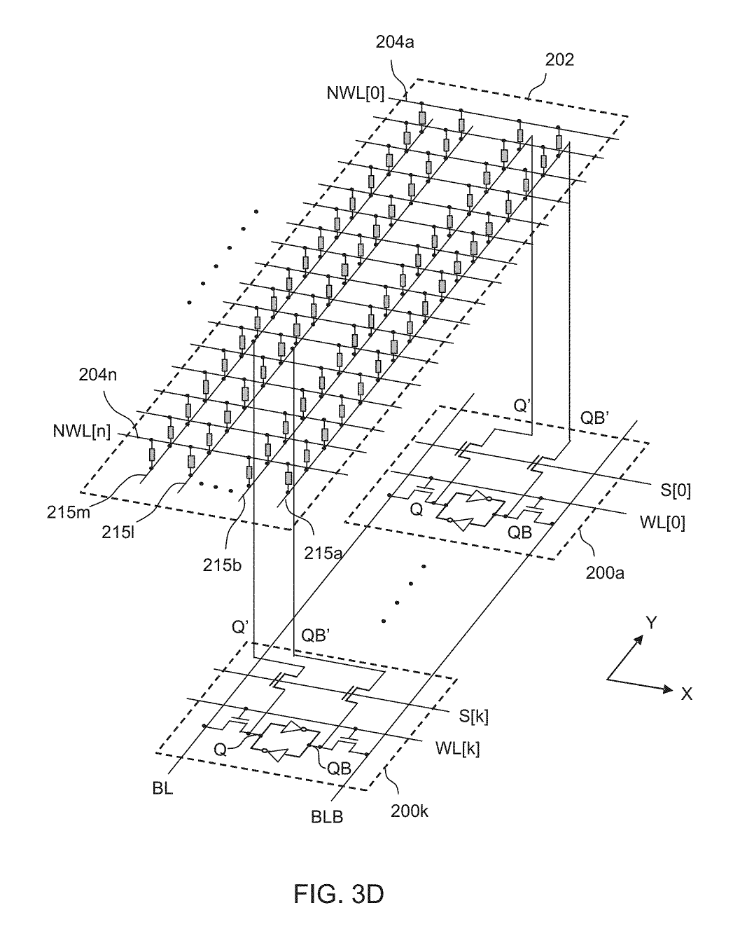

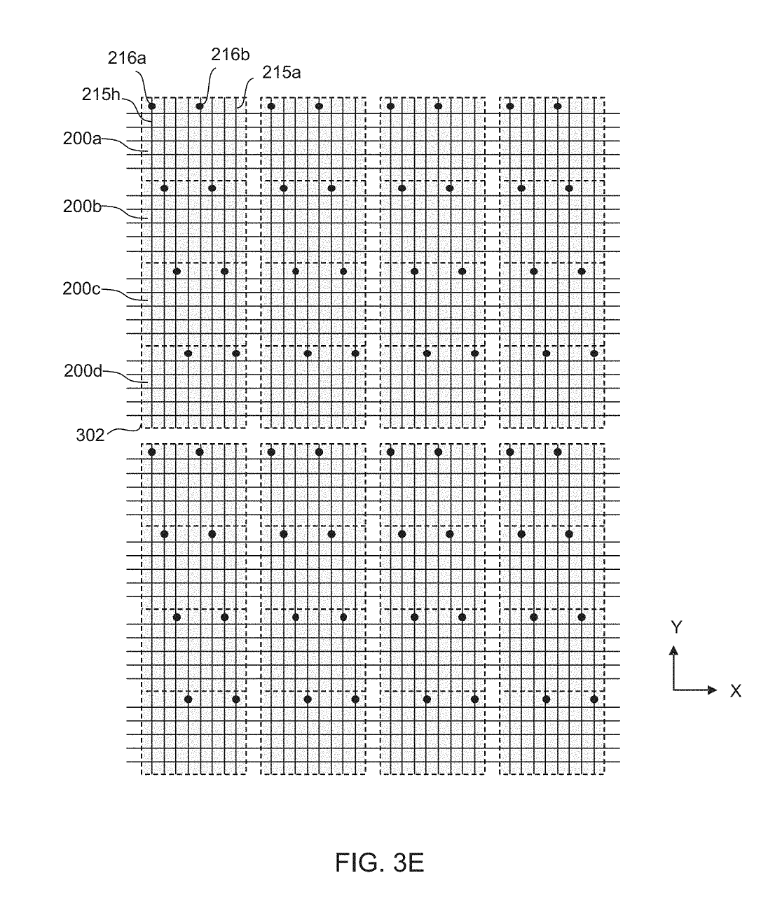

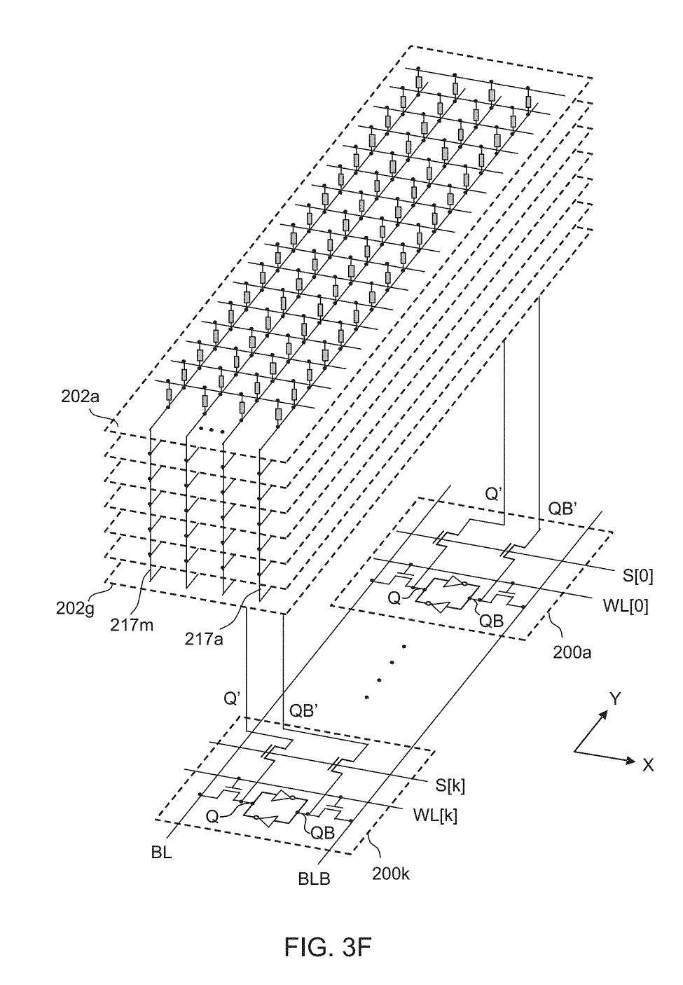

FIG. 3A shows an exemplary embodiment of a circuit that is based on the circuit shown in FIG. 2I. This circuit is similar to the circuit shown in FIG. 1B except that the switches M1 213a and M2 213b are connected to different control signals (S1) and (S2). This allows first data in the Q node to be read from or written to the NVM cells 203a, and second data in the QB node to be read from or written to the NVM cell 203b, independently. Therefore, the cells 203a and 203b may store different data. This doubles the non-volatile memory's data density.

FIG. 3B shows an exemplary embodiment of a circuit that implements an S-NVM cell. In this embodiment, the SRAM cell 200 has multiple switches on the Q and QB sides, such as M1 213a to M4 213d for example. This allows the SRAM cell's Q and QB nodes to be connected to multiple non-volatile memory bit lines, such as bit line 201a to bit line 201d. This increases the density of the non-volatile memory because the pitch of the NVM bit lines is normally much smaller than the pitch of the SRAM cell.

FIG. 3C shows an exemplary embodiment of a circuit that implements an S-NVM cell. In this circuit, the NVM array 202 has a three-dimensional (3D) array structure that contains multiple NVM layers of NVM cells, such as layer 202a to layer 202m as shown. The bit lines of the multiple NVM layers are connected by using metal lines or vias, as shown by the connections 201a-d. This configuration increases the density of the NVM arrays.

FIG. 3D shows an exemplary embodiment of a circuit that implements an S-NVM cell. In this circuit, a RRAM array 202 is located on top of SRAM cells 200a-k. The RRAM array 202 contains multiple word lines 204a-n and multiple bit lines 215a-m. The total number of the SRAM cells 200a-k may be half of the number of the RRAM bit lines 215a-m. The Q′ and QB′ nodes of the SRAM cells 200a-k are connected to the RRAM bit lines 215a-m. For example, the Q′ and QB′ nodes of the SRAM cell 200a are connected to the bit lines 215a and 215b, and the Q′ and QB′ nodes of the SRAM cell 200k are connected to the bit lines 2151 and 215m. The RRAM bit lines and SRAM cells can be connected in virtually any order. By using this structure, the RRAM array can use the minimal cell pitch to maximize array density without using the multiple switch structure shown in FIG. 3B.

In an exemplary embodiment, the structure shown in FIG. 3D can be referred to as an array unit. A large-density array can be formed by repeating the array unit structure shown in FIG. 3D in both the X and Y directions.

FIG. 3E shows a top view of an embodiment of large S-NVM array that comprises eight array units as shown in FIG. 3D. Each array unit contains four SRAM cells such as SRAM cells 200a-d shown in array unit 302. As illustrated in the array unit 302, the SRAM cells' Q and QB nodes are connected to eight bit lines 215a-h of the NVM array through contacts or vias, such as 216a and 216b.

FIG. 3F shows another exemplary embodiment of an array unit. This array unit comprises, multiple layers 202a-g of RRAM cells. The bit lines of each layer are connected by using metal layers and vias, as shown by bit lines 217a-m. The bit lines of the bottom layer 202g are connected to the Q and QB nodes of the SRAM cells 200a-k.

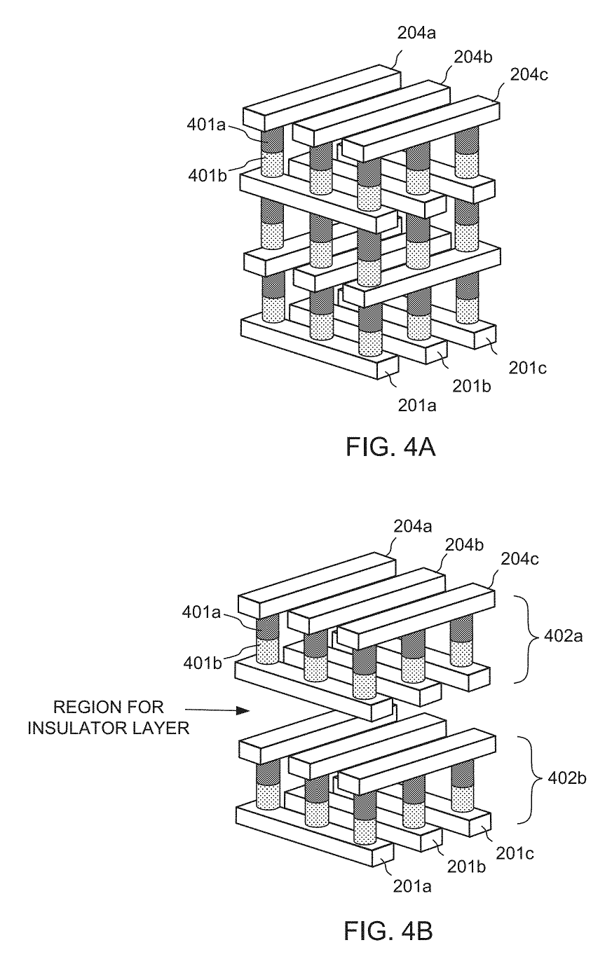

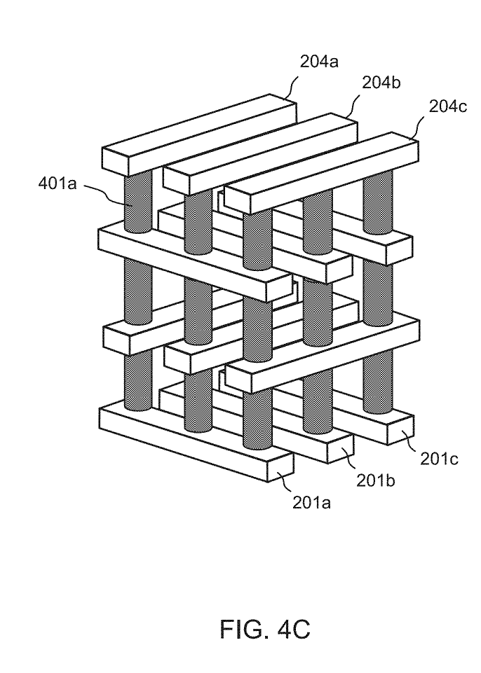

FIGS. 4A-C show exemplary embodiments of the 3D NVM array structures for use with large S-NVM arrays.

In FIG. 4A, the array structure comprises word lines 204a-c and bit lines 201a-c. The word lines and bit lines run in different directions. The array also comprises resistive elements, such as resistive element 401a, and selectors, such as selector 401b.

In FIG. 4B, the layers 402a and 402b of the array structure are separated by an insulator layer placed in an insulator region between the layers.

FIG. 4C shows another exemplary embodiment of a NVM array structure. In this embodiment, the NVM cell comprises only resistive elements, such as resistive element 401a, without selector elements. This cell structure may have leakage current issue because there is no selector. Therefore, it may be necessary to applied more complicated bias conditions to the unselected word lines and bit lines to overcome the leakage current issue. Similarly, the cell structure in FIG. 4C can be divided similar to the array embodiment shown in FIG. 4B.

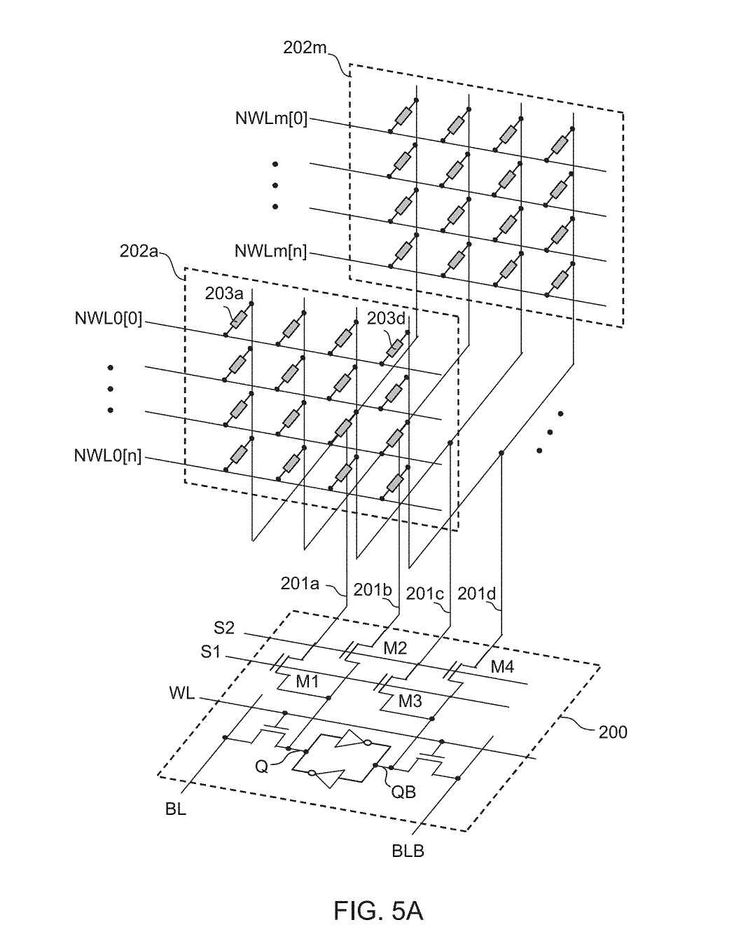

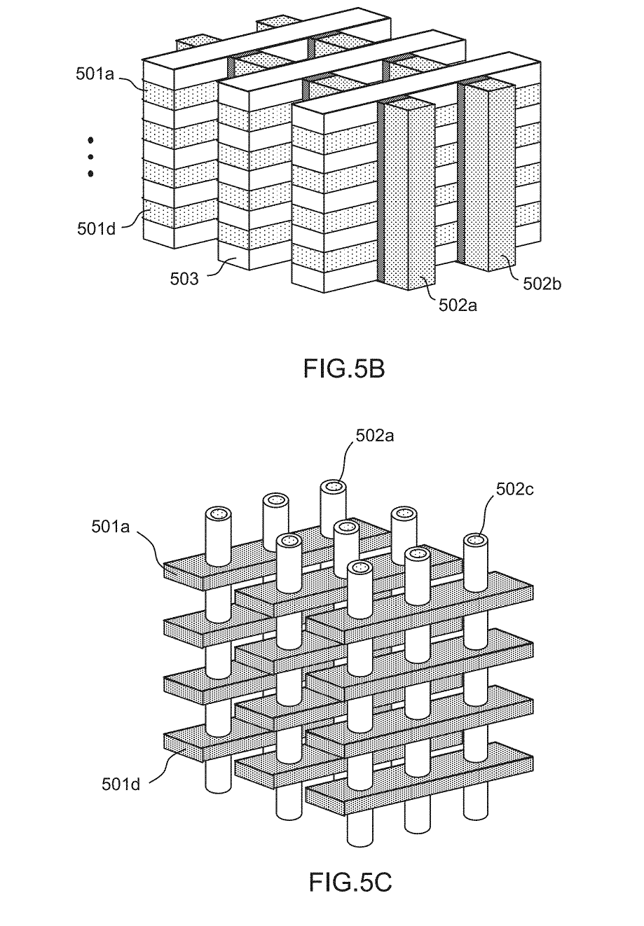

FIG. 5A shows an exemplary embodiment of a circuit that implements a 3D S-NVM array unit. The 3D S-NVM array unit comprises multiple layers 202a-m of NVM that run in a vertical direction while the SRAM cell runs in a horizontal direction.

FIGS. 5B-C show exemplary embodiments of 3D NVM array structures. These array structures comprise word lines 501a-d and bit lines 502a-c. The layer 503 is an insulator layer that is formed between the word lines. The NVM storage cells are located at the intersections of the word line and bit lines.

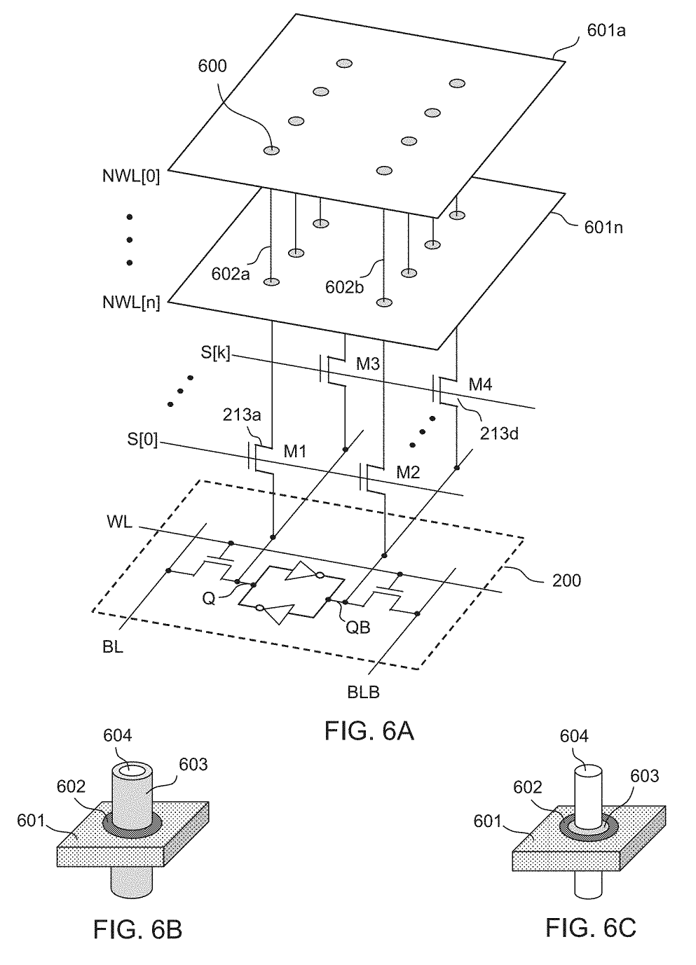

FIG. 6A shows an exemplary embodiment of a circuit that implements a 3D S-NVM array unit. The 3D S-NVM array unit comprises multiple word line layers, such as layers 601a-n as shown. The array unit also comprises vertical bit lines, such as 602a and 602b. The word line layers comprises NVM cells, such as NVM cell 600 that comprises a RRAM or PCM cell, for example. The vertical bit lines are connected to the SRAM cell through vertical or planar transistors M1 213a to M4 213d. The vertical transistors may be junction or junction-less transistors.

FIGS. 6B-C show exemplary embodiments of RRAM cells for use as the NVM cells shown in FIG. 6A. For example, the RRAM cell is suitable for use as the NVM cell 600 shown in FIG. 6A. The RRAM cell comprises word line layer 601, selector layer 602, resistive layer 603 and bit line layer 604. In another embodiment, the selector layer 602 and the resistive layer 603 can be exchanged.

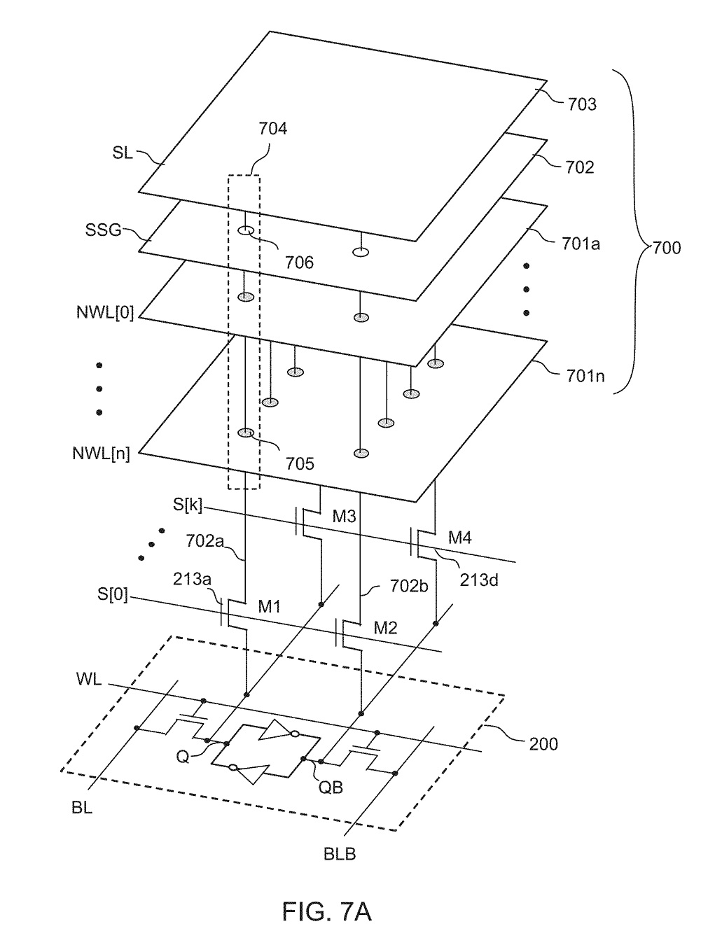

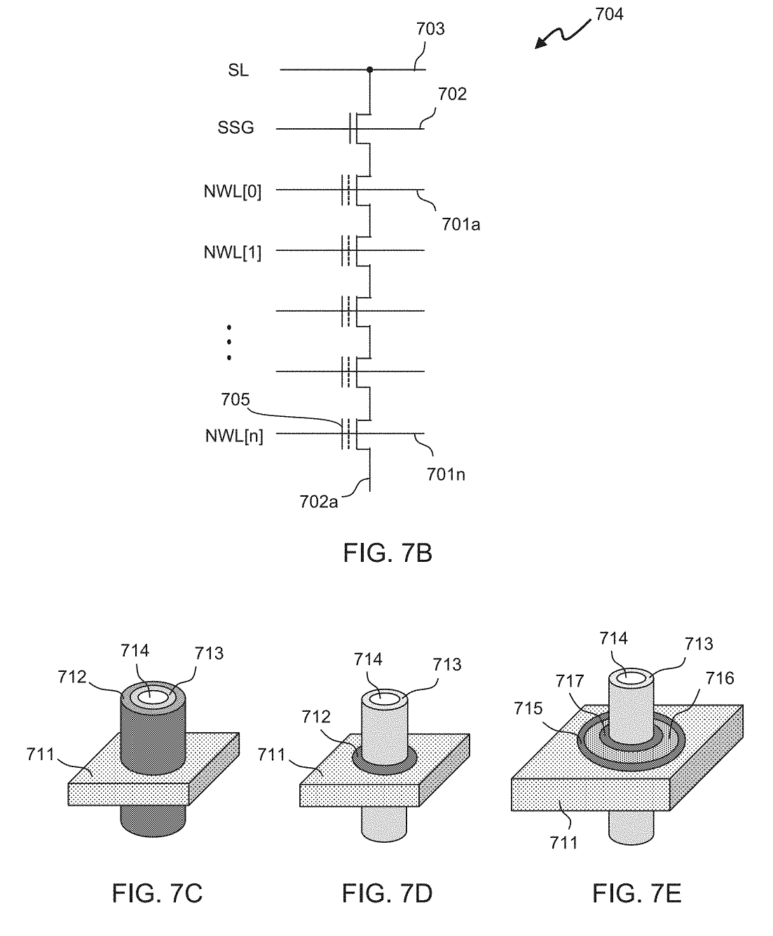

FIG. 7A shows an exemplary embodiment of a circuit that implements a 3D S-NVM array unit. The circuit comprises a non-volatile memory array 700 that is a 3D NAND type flash memory. The memory 700 comprises multiple word line layers 701a-n, a source select gate (SSG) layer 702, and a source line (SL) layer 703. The flash memory 700 comprises bit strings, such as bit string 704, that are connected to the SRAM cell's Q and QB nodes through select transistors, such as M1 213a to M4 213d. The memory 700 comprises NAND flash memory cells, such as memory cell 705, and vertical transistors, such as vertical transistor 706.

FIG. 7B shows an exemplary embodiment of an equivalent circuit of the bit string 704 shown in FIG. 7A. As shown in FIG. 7B, the bit string 704 comprises SL 703, SSG 702, word lines 701a-n, and connection 702a to select transistor M1 213a.

FIGS. 7C-E show exemplary embodiments of cell structures for use as the NAND flash memory cell 705 shown in FIG. 7A.

FIG. 7C shows an embodiment of a cell structure that comprises a word line conductor layer 711 and a charge-trapping layer 712, such as an ONO (oxide-nitride-oxide) layer. The cell structure also comprises a silicon or polysilicon layer 713 as the cell's channel region. The cell structure also comprises an insulator core 714.

FIG. 7D shows another embodiment of the cell structure shown in FIG. 7C where a portion of the charge-trapping layer 712 has been removed so that it is flush with the word line conductor layer 711.

FIG. 7E shows another exemplary embodiment of a cell structure using floating gate technology. This cell structure comprises an ONO layer 715, a floating gate layer 716, and a tunnel oxide layer 717.

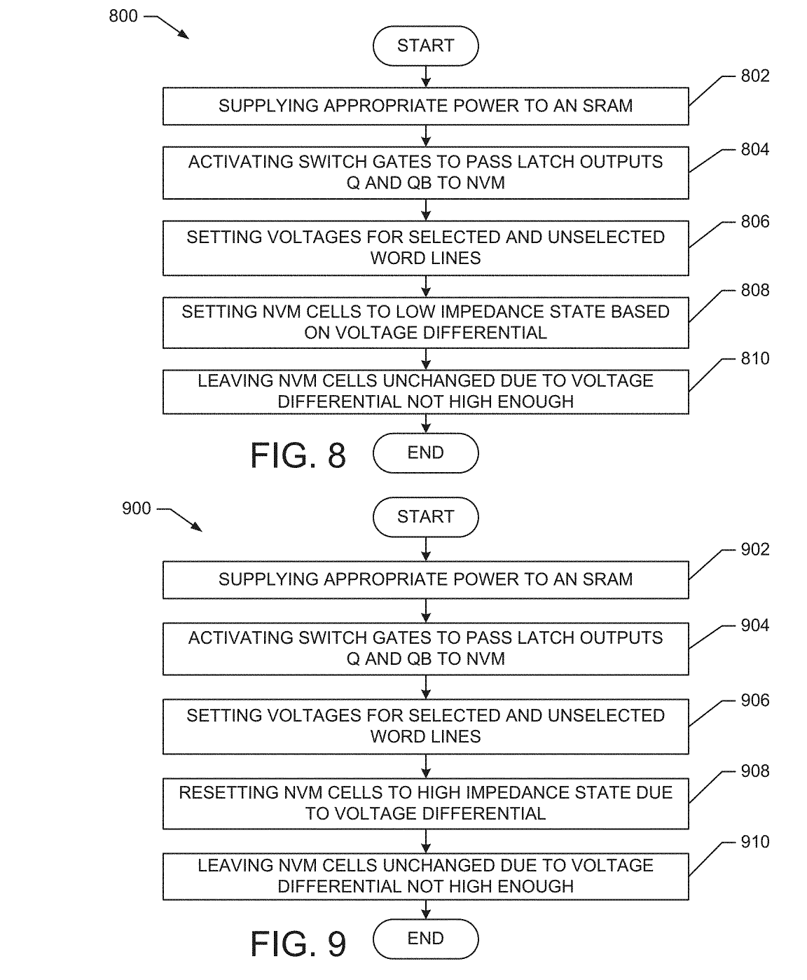

FIG. 8 shows an exemplary embodiment of method 800 for transferring data from an SRAM cell to a NVM cell. For example, the method is suitable for use with the RRAM array shown in FIG. 2C to write a ‘1’ from the node Q to the RRAM cell 210a. It will be assumed that the RRAM cells 210 have a Vt that is 1V, Vset is 2V and Vres is 2V.

At block 802, power is supplied to the SRAM. For example, the power lines (VH) of the SRAM's latch are supplied with a voltage higher than Vset. For example, since Vset is 2 volts, the power lines of the SRAM's latch are supplied with 2.5 volts.

At block 804, switch gates are controlled to pass Q and QB to bit lines of the NVM. For example, the control signal (S1) of the switches 213a and 213b is supplied with a voltage higher than [Vset+Vt], such as 3.5V, to enable the switches to pass Vset and 0V (from Q and QB) to the bit lines 211a and 211b, respectively.

At block 806, word line voltages are set for selected and unselected word lines. For example, a selected NVM word line, NWL (sel) 212a, and unselected NVM word line, NWL (unsel) 212b, are supplied with 0V and an inhibit voltage (Vinh) such as 1V, respectively.

At block 808, a voltage difference across the RRAM cell sets the cell to a low impedance state (e.g., data ‘1’). For example, as a result of the voltage difference across the RRAM cell 210a, the resistance of the RRAM cell 210a will be set to a low impedance state. For example, the voltage difference is the difference between the selected word line and the bit line attached to the RRAM cell.

At block 810, cells associated with unselected word lines will not be set. For example, the RRAM cells 210b, 210c, and 210d will not be set due to the fact that the voltage differences across these cells are not high enough.

Thus, the method 800 operates to transfer data from an SRAM cell to a NVM cell. It should be noted that the method 800 is exemplary and that the disclosed operations may be combined, rearranged, added to, deleted, and/or modified within the scope of the embodiments.

FIG. 9 shows an exemplary embodiment of method 900 for transferring data from an SRAM cell to a NVM cell. For example, the method is suitable for use with the RRAM array shown in FIG. 2D to write a “0” from the node QB to the RRAM cell 210b. It will be assumed that the RRAM cells 210 have a Vt that is 1V, Vset is 2V and Vres is 2V.

At block 902, power is supplied to the SRAM. For example, the power lines (VH) of the SRAM's latch are supplied with an inhibit voltage (Vinh), such as 1 volt.

At block 904, switch gates are controlled to pass Q and QB to bit lines of the NVM. For example, the control signal (S1) of the switches 213a and 213b is supplied with a voltage higher than [Vinh+Vt], such as 2 volts, to enable the switches to pass Vinh and 0V (from Q and QB) to the bit lines 211a and 211b, respectively.

At block 906, word line voltages are set for selected and unselected word lines. For example, a selected NVM word line, NWL (sel) 212a, and unselected NVM word line, NWL (unsel) 212b, are supplied with Vres and an inhibit voltage (Vinh), such as 2.5 volts and 1 volt, respectively.

At block 908, a voltage difference across the NVM cell resets the cell to a high impedance state (e.g., data ‘0’). For example, as a result of the voltage difference across the RRAM cell 210b, the resistance of the RRAM cell 210b will be reset to a high impedance state.

At block 910, cells associated with unselected word lines will not be reset. For example, the RRAM cells 210a, 210c, and 210d will not be reset due to the fact that the voltage differences across these cells are not high enough.

Thus, the method 900 operates to transfer data from an SRAM cell to a NVM cell. It should be noted that the method 900 is exemplary and that the disclosed operations may be combined, rearranged, added to, deleted, and/or modified within the scope of the embodiments.

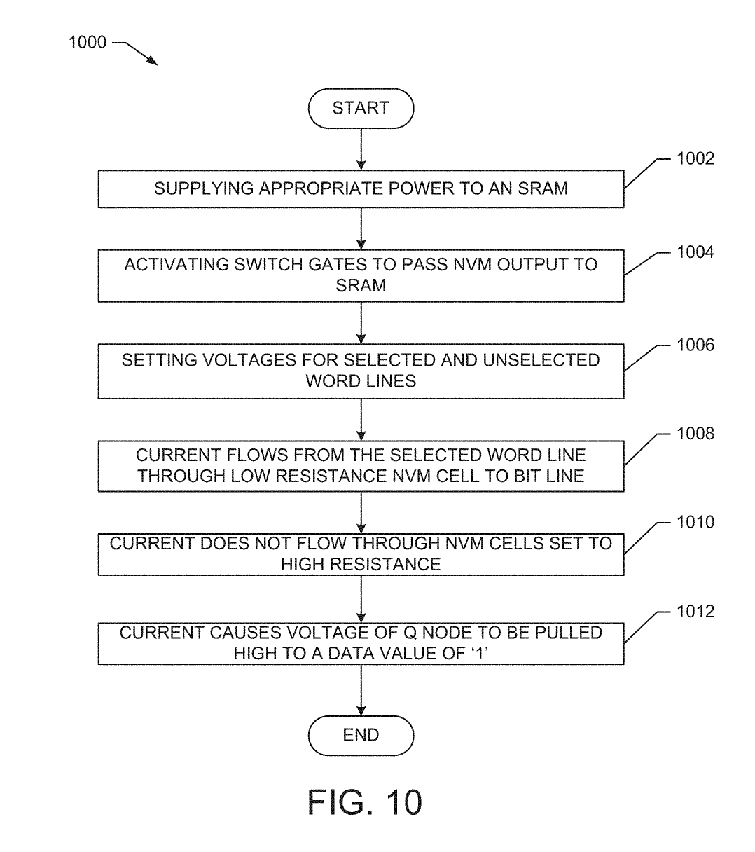

FIG. 10 shows an exemplary embodiment of method 1000 for transferring data from a NVM cell to an SRAM cell. For example, the method is suitable for use with the S-RRAM cell shown in FIG. 2E to read data from RRAM cell 210a and transfer the data to the node Q of the SRAM cell.

At block 1002, an appropriate power is supplied to the SRAM. For example, the VH of the SRAM latch is set to VDD.

At block 1004, switch gates are activated to pass NVM output to the SRAM. For example, the control signal (S1) of the switches 213a and 213b is supplied with VDD.

At block 1006, voltages for selected and unselected word lines are set. For example, the selected NWL 212a is supplied with a read voltage (Vread) higher than Vt of the RRAM cells, such as VDD.

At block 1008, assuming the RRAM cell 210a is set to low resistance, current will flow from the selected NWL 212a through the RRAM cell 210a to the bit line 211a.

At block 1010, assuming that the RRAM cell 210b is reset to a high resistance, current will not flow through the RRAM cell 210b.

At block 1012, the voltage of node Q will be pulled up to flip the data of the Q node of the SRAM cell to ‘1’ due to the current flow through the RRAM cell 210a.

Thus, the method 1000 operates to transfer data from a NVM cell to an SRAM cell. It should be noted that the method 1000 is exemplary and that the disclosed operations may be combined, rearranged, added to, deleted, and/or modified within the scope of the embodiments.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A memory cell, comprising:
a static random-access memory (SRAM) cell having Q and QB nodes;
a non-volatile memory (NVM) array having a plurality of NVM cells, wherein each NVM cell comprises a memory element and a selector; and
select gates that selectively couple at least one of the Q and QB nodes to the plurality of NVM cells.

2. The memory cell of claim 1, wherein each selector comprises one of a silicon diode, Schottky diode, Tunnel barrier based selector, mixed ionic-electron conduction selector or special metal-oxide material that has threshold behavior selected from materials comprising NbOx, ZrOx, TiOx, and CuGeS.

3. The memory cell of claim 1, wherein the NVM array is located on top of the SRAM cell.

4. The memory cell of claim 1, wherein the NVM array is located in the back-end of line (BEOL).

5. The memory cell of claim 1, wherein the NVM array is located on a wafer or chip that is separate from the SRAM cell.

6. The memory cell of claim 1, wherein the select gates are controlled by multiple control signals.

7. The memory cell of claim 1, wherein the NVM array comprises a first bit line coupled to the Q node and a second bit line coupled to the QB node.

8. The memory cell of claim 7, wherein the NVM array comprises a first plurality of NVM cells coupled the first bit line and a second plurality of NVM cells coupled to the second bit line.

9. The memory cell of claim 8, further comprising a first transistor that couples the Q node to the second bit line and a second transistor that couples the eQB node to the first bit line.

10. The memory cell of claim 1, wherein the NVM array comprises a 3D array having multiple layers of NVM cells that are stacked on top of the SRAM cell.

11. The memory cell of claim 10, wherein selected NVM cells in each layer are coupled to at least one of the Q and QB nodes.

12. The memory cell of claim 10, wherein the multiple layers are stacked horizontally or vertically.

13. The memory cell of claim 10, wherein the SRAM and the 3D array having the multiple layers of NVM cells forms an array unit, and wherein multiple array units are combined to form a large memory array.

14. The memory cell of claim 1, wherein the memory element comprises a variable resistor.

15. The memory cell of claim 1, wherein the memory element comprises a variable capacitor.

16. The memory cell of claim 1, wherein the memory element comprises a phase-change material (PCM).

17. The memory cell of claim 1, wherein the memory element comprises a magnetoresistive material (MRAM).

18. The memory cell of claim 1, wherein the memory element comprises a ferroelectric material (FRAM).

19. A method for operating a memory cell comprising a static random-access memory (SRAM) cell having Q and QB nodes and a non-volatile memory (NVM) array, the method comprising:
coupling at least one of the Q and QB nodes to at least one bit line, respectively, of the NVM array;
setting voltage levels for selected and unselected word lines of the NVM array;
setting a first NVM cell connected to a selected word line to a low impedance state, if a voltage differential between the selected word line and a bit line connected to the first NVM cell exceeds a first threshold level;
resetting a second NVM cell connected to the selected word line to a high impedance state, if a voltage differential between the selected word line and a bit line connected to the second NVM cell exceeds a second threshold level; and
leaving NVM cells connected to the unselected word lines unchanged.

20. A method for operating a memory cell comprising a static random-access memory (SRAM) cell having Q and QB nodes and a non-volatile memory (NVM) array, the method comprising:
coupling the Q node to a bit line of the NVM array;
setting voltage levels for selected and unselected word lines, wherein current flows to the Q node, if a NVM cell connected a selected word line is in a low impedance state; and
setting the Q node of the SRAM cell to a data value of ‘1’ if the current flows.
